(19) United States
(12) Patent Application Publication
(10) Pub. No.: US 2026/0120726 A1
(43) Pub. Date: Apr. 30, 2026

(54) MEMORY DEVICE

(71) Applicant: Samsung Electronics Co., Ltd., Suwon-si (KR)

(72) Inventors: Kiseok Lee, Suwon-si (KR); Minsoo Kim, Suwon-si (KR); Yongkwan Kim, Suwon-si (KR); Huijung Kim, Suwon-si (KR); Taejin Park, Suwon-si (KR); Sungsoo Yim, Suwon-si (KR); Hyunyong Jeong, Suwon-si (KR); Hyungeun Choi, Suwon-si (KR)

(21) Appl. No.: 19/003,663

(22) Filed: Dec. 27, 2024

(30) Foreign Application Priority Data
Jul. 4, 2024 (KR) 10-2024-0088052

(51) Int. Cl. G11C 5/06; G11C 11/408; G11C 11/4091

(52) U.S. Cl. CPC G11C 5/063; G11C 11/4085; G11C 11/4091

(57) ABSTRACT

A memory device including a memory cell array circuit having a plurality of sub-cell regions disposed in a first direction and a second direction, the plurality of sub-cell regions respectively including a plurality of memory cells and a core circuit including a plurality of unit regions respectively overlapping at least one sub-cell region, among the plurality of sub-cell regions, in a third direction, perpendicular to the first direction and the second direction. Each of the plurality of unit regions includes a first to fourth regions adjacent to each other. The first region and the third region include a bit line sense amplifier circuit and a processing in memory (PIM) circuit adjacent and connected to the bit line sense amplifier circuit. The second region and the fourth region include a sub-word line driver circuit and a row driver circuit next to the sub-word line driver circuit in the first direction.

### CROSS-REFERENCE TO RELATED APPLICATION(S)

This application claims the benefit of priority to Korean Patent Application No. 10-2024-0088052 filed on Jul. 4, 2024, in the Korean Intellectual Property Office, and all the benefits accruing therefrom under 35 U.S. C. 119, the disclosure of which is incorporated herein by reference in its entirety.

### BACKGROUND

The present disclosure relates to a memory device.

With demand for miniaturization, multifunctionalization, and high performance of electronic products, a high-capacity integrated circuit device is required. As the feature size of a memory device such as a DRAM device decreases, an efficient arrangement of circuits for driving a memory device is required.

### SUMMARY

An aspect of the present disclosure is to provide a memory device in which a core circuit for driving the memory cell array may be effectively disposed, and which may efficiently perform arithmetic operations of data input/output from the memory cell array.

A memory device according to an example embodiment of the present disclosure, includes: a memory cell array circuit including a plurality of sub-cell regions disposed in a first direction and a second direction, the plurality of sub-cell regions respectively including a plurality of memory cells respectively connected to a plurality of word lines extending in the first direction and a plurality of bit lines extending in the second direction, the second direction intersecting the first direction; and a core circuit including a plurality of unit regions respectively overlapping at least one sub-cell region, among the plurality of sub-cell regions, in a third direction, perpendicular to the first direction and the second direction, wherein each of the plurality of unit regions includes a first region, a second region adjacent to the first region in the first direction, a third region adjacent to the second region in the second direction, and a fourth region adjacent to the third region in the first direction, and the fourth region is adjacent to the first region in the second direction, wherein the first region and the third region include a bit line sense amplifier circuit respectively connected to the plurality of bit lines, and a processing in memory (PIM) circuit adjacent to the bit line sense amplifier circuit in the second direction and connected to the bit line sense amplifier circuit, and wherein the second region and the fourth region include a sub-word line driver circuit respectively connected to the plurality of word lines, and a row driver circuit included in a region adjacent to the sub-word line driver circuit in the first direction.

A memory device according to an example embodiment of the present disclosure includes: a first semiconductor layer including a first substrate, and including a plurality of sub-cell blocks including a plurality of word lines extending in a first direction, parallel to an upper surface of the first substrate, a plurality of bit lines extending in a second direction, parallel to the upper surface of the first substrate and intersecting the first direction, a plurality of memory cells connected to the plurality of bit lines and the plurality of word lines, a plurality of first through silicon vias (TSVs) contacting the plurality of bit lines and spaced apart from the plurality of memory cells in the second direction, and a plurality of second TSVs contacting the plurality of word lines and spaced apart from the plurality of memory cells in the first direction; and a second semiconductor layer including a second substrate including a plurality of unit regions overlapping the plurality of sub-cell blocks on the first surface, wherein each of the plurality of unit regions includes first to fourth regions adjacent to each other in the first direction and the second direction and defined in a clockwise order on the upper surface of the first substrate, wherein the first region and the third region include a bit line sense amplifier circuit electrically connected to the plurality of bit lines through the plurality of first TSVs, respectively, and a processing in memory (PIM) circuit connected to the bit line sense amplifier circuit through conductive patterns, and wherein the second region and the fourth region include a sub-word line driver circuit respectively connected to the plurality of word lines through the plurality of second TSVs, and a row decoder circuit connected to the sub-word line driver circuit through conductive patterns.

A memory device according to an example embodiment of the present disclosure includes: a first semiconductor layer including a first substrate including a plurality of unit regions on an upper surface thereof, wherein the plurality of unit regions include first to fourth regions adjacent to each other in a first direction and a second direction, parallel to an upper surface of the first substrate and defined in a clockwise order, each of the first region and the third region includes a bit line sense amplifier circuit and a processing in memory (PIM) circuit connected to the bit line sense amplifier circuit, and the second region and the fourth region include a sub-word line driver circuit and a row decoder circuit connected to the sub-word line driver circuit; and a second semiconductor layer disposed on the first semiconductor layer and including a plurality of memory cell structures respectively including a plurality of word lines extending in a first direction, parallel to an upper surface of the first substrate, a plurality of bit lines extending in a second direction, parallel to the upper surface of the first substrate and intersecting the first direction, and a plurality of memory cells connected to the plurality of bit lines and the plurality of word lines, wherein the second semiconductor layer includes: a plurality of first through silicon vias (TSVs) overlapping the first region and the third region in a third direction, perpendicular to the first substrate, and electrically connecting the plurality of bit lines and the bit line sense amplifier circuit in a position adjacent to one of the plurality of memory cell structures in the second direction; and a plurality of second TSVs overlapping the second region and the fourth region in the third direction, and electrically connecting the plurality of word lines and the sub-word line driver circuit in the position adjacent to one of the plurality of memory cell structures in the first direction.

A memory device according to an example embodiment of the present disclosure includes: a first semiconductor layer including a first substrate including a plurality of unit regions on an upper surface thereof, wherein the plurality of unit regions include first to fourth regions adjacent to each other in a first direction and a second direction, parallel to the upper surface of the first substrate and defined in a clockwise order, each of the first region and the third region includes a bit line sense amplifier circuit and a processing in memory (PIM) circuit connected to the bit line sense amplifier circuit, and the second and fourth regions include a sub-word line driver circuit and a row decoder circuit connected to the sub-word line driver circuit; and a second semiconductor layer disposed below the first semiconductor layer, and including a plurality of memory cell structures respectively including a plurality of word lines extending in the first direction, a plurality of bit lines extending in the second direction, and a plurality of memory cells connected to the plurality of bit lines and the plurality of word lines, wherein the first semiconductor layer further includes: a plurality of first through silicon vias (TSVs) electrically connecting the plurality of bit lines and the bit line sense amplifier circuit in a position adjacent to one of the plurality of memory cell structures in the first direction, in the first region and the third region; and a plurality of second TSVs electrically connecting the plurality of word lines and the sub-word line driver circuit in a position adjacent to one of the plurality of memory cell structures in the second direction, in the second region and the fourth region.

In a memory device according to an example embodiment of the present disclosure, the core circuit may be disposed to overlap a memory cell array in a vertical direction, and a processing in memory (PIM) circuit may be disposed in the core circuit. Accordingly, the PIM may be disposed without increasing an area of the memory device.

In a memory device according to an example embodiment of the present disclosure, since the PIM circuit is disposed adjacent to a path by which data is input and output from the memory cell array, a data transfer path between the memory cell array and the PIM circuit may be shortened, and energy efficiency for calculating the data may increase.

The aspects to be solved by the present disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating a memory device according to an example embodiment of the present disclosure;

FIG. 2 is a perspective view illustrating a semiconductor device according to an example embodiment of the present disclosure;

FIGS. 3 and 4 are views illustrating a layout of a unit control circuit according to an example embodiment of the present disclosure;

FIGS. 5A and 5B are views illustrating a unit region and a sub-cell region according to an example embodiment of the present disclosure;

FIGS. 6A and 6B are views illustrating a core circuit region and a sub-cell region according to an example embodiment of the present disclosure;

FIG. 7 is a view illustrating an example of a cross-section taken along lines I-I′ and II-II′ of FIG. 4;

FIG. 8 is a view illustrating an example of a cross-section taken along lines I-I′ and II-II′ of FIG. 4;

FIG. 9 is a view illustrating an example of a cross-section taken along line II-II′ of FIG. 4;

FIGS. 10 and 11 are views illustrating a layout of a unit control circuit according to an example embodiment of the present disclosure;

FIG. 12 is a view illustrating an example of a cross-section taken along line III-III′ of FIG. 11;

FIG. 13 is a view illustrating an example of a cross-section taken along line III-III′ of FIG. 11;

FIG. 14 is a view illustrating a core circuit region according to an example embodiment of the present disclosure;

FIGS. 15A and 15B are views illustrating a core circuit region and a sub-cell region according to an example embodiment of the present disclosure;

FIGS. 16A and 16B are views illustrating a core circuit region and a sub-cell region according to an example embodiment of the present disclosure;

FIG. 17 is a view illustrating a core circuit region according to an example embodiment of the present disclosure;

FIGS. 18A and 18B are views illustrating a core circuit region and a sub-cell region according to an example embodiment of the present disclosure;

FIGS. 19A and 19B are views illustrating a core circuit region and a sub-cell region according to an example embodiment of the present disclosure;

FIGS. 20A and 20B are views illustrating a core circuit region and a sub-cell region according to an example embodiment of the present disclosure;

FIG. 21 is a view illustrating a core circuit region according to an example embodiment of the present disclosure;

FIGS. 22A and 22B are views illustrating a core circuit region and a sub-cell region according to an example embodiment of the present disclosure;

FIG. 23 is a view illustrating a core circuit region according to an example embodiment of the present disclosure;

FIGS. 24A and 24B are views illustrating a core circuit region and a sub-cell region according to an example embodiment of the present disclosure;

FIGS. 25A and 25B are views illustrating a core circuit region and a sub-cell region according to an example embodiment of the present disclosure;

FIG. 26 is a view illustrating a core circuit region according to an example embodiment of the present disclosure; and

FIGS. 27A and 27B are views illustrating a core circuit region and a sub-cell region according to an example embodiment of the present disclosure.

### DETAILED DESCRIPTION

Hereinafter, example embodiments of the present disclosure will be described with reference to the accompanying drawings.

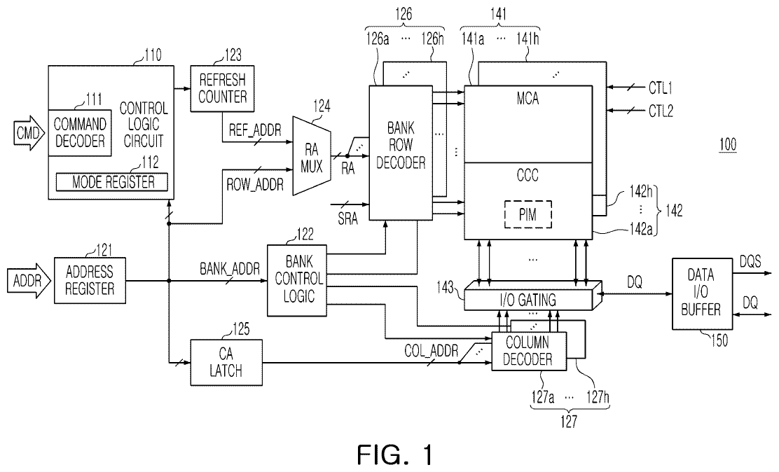

FIG. 1 is a view illustrating a memory device according to an example embodiment of the present disclosure.

Referring to FIG. 1, a memory device 100 may include a control logic circuit 110, an address register 121, a bank control logic 122, a refresh counter 123, a row address multiplexer 124, a column address latch 125, a row decoder 126, a column decoder 127, a memory core circuit 141, a sense amplifier 142, an input/output gate circuit 143, and a data input/output buffer 150.

The memory core circuit 141 may include a plurality of memory core circuits 141a to 141h. Additionally, the plurality of row decoders 126 (126a to 126h), the plurality of column decoders 127 (127a to 127h), and the plurality of sense amplifiers 142 (142a to 142h) may be respectively connected to the plurality of memory core circuits 141a to 141h.

The plurality of memory core circuits 141a to 141h, the plurality of sense amplifiers 142a to 142h, the plurality of column decoders 127a to 127h, and the plurality of row decoders 126a to 126h may respectively be included in a plurality of banks.

Each of the plurality of memory core circuits 141a to 141h may include a memory cell array MCA and a core control circuit CCC. The memory cell array MCA may include a plurality of word lines, a plurality of bit lines, and a plurality of memory cells connected to the plurality of word lines and the plurality of bit lines.

The core control circuit CCC may include circuits for controlling the memory cell array MCA. For example, the core control circuit CCC may include a sub-word line driver circuit for driving the plurality of word lines, and a bit line sense amplifier circuit for detecting voltage changes of the plurality of bit lines and amplifying the voltage changes.

The address register 121 may receive an address ADDR including a bank address BANK_ADDR, a row address ROW_ADDR, and a column address COL_ADDR from a memory controller connected to the memory device 100. The address register 121 may provide the received bank address BANK_ADDR to the bank control logic 122, may provide the received row address ROW_ADDR to the row address multiplexer 124, and may provide the received column address COL_ADDR to the column address latch 125.

The bank control logic 122 may generate bank control signals in response to the bank address BANK_ADDR. In response to the bank control signals, a row decoder corresponding to the bank address BANK_ADDR, among the plurality of row decoders 124a to 124h may be activated, and a column decoder corresponding to the bank address BANK_ADDR, among the plurality of column decoders 127a to 127h, may be activated.

The row address multiplexer 124 may receive the row address ROW_ADDR from the address register 121, and may receive a refresh row address REF_ADDR from the refresh counter 123. The row address multiplexer 124 may selectively output the row address ROW_ADDR or the refresh row address REF_ADDR as a row address RA. The row address RA output from the row address multiplexer 124 may be applied to each of the plurality of row decoders 126a to 126h.

The refresh counter 123 may sequentially increase or decrease the refresh row address REF_ADDR according to the control of the control logic circuit 110.

The row decoder activated by the bank control logic 122, among the plurality of row decoders 126a to 126h, may decode the row address RA output from the row address multiplexer 124 to activate a word line corresponding to the row address. For example, the activated row decoder may apply a word line driving voltage to the word line corresponding to the row address.

The column address latch 125 may receive the column address COL_ADDR from the address register 121, and may temporarily store the received column address COL_ADDR. Additionally, the column address latch 125 may gradually increase the received column address COL_ADDR in a burst mode. The column address latch 125 may apply a temporarily stored or gradually increased column address COL_ADDR to each of the plurality of column decoders 127a to 127h.

A column decoder activated by the bank control logic 122, among the plurality of column decoders 127a to 127h, may activate a sense amplifier corresponding to the bank address BANK_ADDR and the column address COL_ADDR through a corresponding input/output gating circuit 143.

The input/output gating circuit 143 may include input data mask logics, read data latches for storing data output from the plurality of memory core circuits 141a to 141h, and write drivers for writing data to the plurality of memory core circuits 141a to 141h, along with circuits for gating input/output data.

A data signal DQ to be read from one of bank arrays of the plurality of memory core circuits 141a to 141h may be sensed by a sense amplifier corresponding to the one bank array, and may be stored in the read data latches. The data signal DQ stored in the read data latches may be provided to a memory controller together with a data strobe signal DQS.

The data signal DQ to be written to a memory cell array MCA included in one of the plurality of memory core circuits 141a to 141h may be provided to an input/output gating circuit 143 by the data input/output buffer 150. The input/output gating circuit 143 may write the data signal DQ to a target page of the one memory cell array MCA through the write drivers.

The data input/output buffer 150 provides the data signal DQ to the input/output gating circuit 143 in a write operation, and may provide the data signal DQ provided from the input/output gating circuit 143 to the memory controller in a read operation.

The control logic circuit 110 may control an operation of the memory device 100. For example, the control logic circuit 110 may generate control signals so that the memory device 100 performs the write operation or the read operation. The control logic circuit 110 may include a command decoder 111 decoding a command CMD received from the memory controller and a mode register 112 setting an operation mode of the memory device 100.

For example, the command decoder 111 may decode a write enable signal, a row address strobe signal, a column address strobe signal, a chip select signal, and the like, and may generate the control signals corresponding to the command CMD.

The memory device 100 may further include a processing in memory (PIM) circuit performing computational processing on data to be written to a memory cell array MCA or data read from the memory cell array MCA.

When the memory device 100 includes the PIM circuit, the memory device 100 may directly perform computational processing on the data without transmitting the data to an external processor. Accordingly, the amount of data exchanged between the memory device 100 and the processor may be reduced, and energy consumption due to data transmission may be reduced. However, when an area of the memory device 100 increases as the memory device 100 includes the PIM circuit, the energy consumption of the memory device 100 may increase.

According to an example embodiment of the present disclosure, the memory cell array MCA and the core control circuit CCC may be stacked in a direction, perpendicular to a substrate of the memory device 100. For example, the substrate may extend in a first direction (e.g., X-direction) and second direction (e.g., Y-direction), and the memory cell array MCA and the core control circuit CCC may be stacked in a third direction (e.g., Z-direction), which is perpendicular to the first direction and the second direction. An area occupied by a control circuit, such as the bit line sense amplifier circuit and the sub-word line driver circuit included in the core control circuit CCC, may be smaller than an area occupied by the memory cell array MCA.

According to an example embodiment of the present disclosure, the core control circuit CCC may include a PIM circuit. The PIM circuit overlaps a region of a memory cell array MCA, and may be disposed in a region in which the control circuit is not disposed. When the PIM circuit is disposed in a region overlapping the region of a memory cell array MCA, even if the PIM circuit is added to the memory device 100, the area of the memory device 100 may not increase. Additionally, since the PIM circuit may be disposed around the bit line sense amplifier, a data transmission path between the PIM circuit and the bit line sense amplifier circuit may be minimized. Accordingly, the energy consumption of the memory device 100 may be reduced.

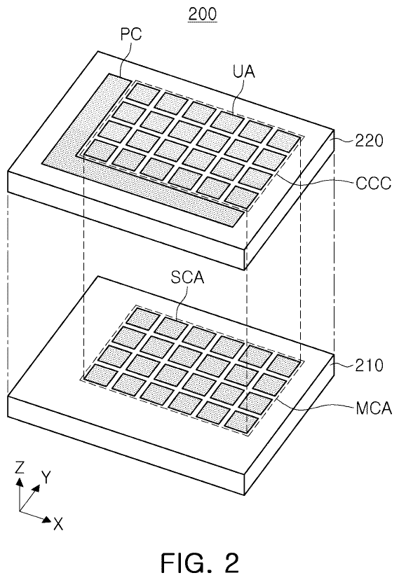

FIG. 2 is a perspective view illustrating a semiconductor device according to an example embodiment of the present disclosure.

Referring to FIG. 2, a memory device 200 may include a first semiconductor layer 210 and a second semiconductor layer 220. The first semiconductor layer 210 and the second semiconductor layer 220 may be stacked in the third direction (Z-direction), perpendicular to an upper surface of a substrate of the memory device 200.

The first semiconductor layer 210 may include a memory cell array MCA, and the second semiconductor layer 220 may include a core control circuit CCC. The memory cell array MCA and the core control circuit CCC of FIG. 2 may correspond to the memory cell array MCA and the core control circuit CCC described with reference to FIG. 1.

Although FIG. 2 exemplifies a case in which the memory device 200 includes one memory cell array MCA and one core control circuit CCC, the present disclosure is not limited thereto. For example, the memory device 200 may include a plurality of memory cell arrays MCA and a plurality of core control circuits CCC.

The memory device 200 may have a PoC (Periphery on Cell) structure in which a second semiconductor layer 220 is stacked on an upper portion of a first semiconductor layer 210. However, the present disclosure is not limited thereto, and the memory device 200 may also have a Cell on Periphery (CoP) structure in which the first semiconductor layer 210 is stacked on an upper portion of a second semiconductor layer 220.

The second semiconductor layer 220 may further include a peripheral circuit PC. For example, the peripheral circuit PC may include a control logic circuit 110, an address register 121, a bank control logic 122, a refresh counter 123, a row address multiplexer 124, a column address latch 125, a row decoder 126, a column decoder 127, a memory core circuit 141, a sense amplifier 142, an input/output gate circuit 143, and a data input/output buffer 150 as described with reference to FIG. 1.

FIG. 2 illustrates a case in which the peripheral circuit PC and the core control circuit CCC are included in the same semiconductor layer, but the peripheral circuit PC and the core control circuit CCC may be included in different semiconductor layers. For example, a memory device according to an example embodiment of the present disclosure may have a three-layer structure in which the memory cell array MCA, the core control circuit CCC, and the peripheral circuit PC are sequentially stacked.

The memory cell array MCA may include a plurality of sub-cell blocks. The plurality of sub-cell blocks may be disposed in the first direction (X-direction) and the second direction (Y-direction), parallel to an upper surface of a substrate of the memory device 200, and intersecting each other. FIG. 2 illustrates a plurality of sub-cell regions SCA in which each of the sub-cell blocks is included.

Each of the plurality of sub-cell blocks may include a plurality of word lines extending in the first direction (X-direction), a plurality of bit lines extending in the second direction (Y-direction), and a plurality of memory cells connected to the plurality of word lines and the plurality of bit lines. In an example embodiment, at least some of the word lines may be shared between the adjacent sub-cell blocks.

When the memory cell array MCA is divided into the plurality of sub-cell blocks, since the number of memory cells connected to one word line is reduced, a load for driving the word line may be reduced.

The core control circuit CCC may include a plurality of unit control circuits for controlling the plurality of sub-cell blocks. FIG. 2 illustrates a plurality of unit regions UA respectively including a plurality of unit control circuits.

In an example embodiment, one unit region UA may overlap one sub-cell region SCA in the third direction (Z-direction), and may control one sub-cell block. For example, one unit region UA may include a sub-word line driver circuit for driving word lines included in the sub-cell block, a bit-line sense amplifier circuit for sensing and amplifying a signal of a bit line included in the sub-cell block, a row decoder circuit for generating a control signal for the word lines, and a power circuit for supplying power to circuits included in the unit control circuit. Additionally, the unit region UA may further include a PIM circuit.

However, the present disclosure is not limited to one unit region UA overlapping one sub-cell region SCA, and one unit region UA may overlap a plurality of adjacent sub-cell regions SCA and control a plurality of sub-cell blocks.

In an example embodiment, the memory device 200 may further include a PIM circuit in another region in addition to the PIM circuit included in the unit region UA. For example, the peripheral circuit PC may further include a global PIM circuit. As a first example, the global PIM circuit may be adjacent to the core control circuit CCC in the second direction (Y-direction), a direction in which the bit lines extend. As a second example, when the memory device has a three-layer structure, the global PIM circuit may overlap the core control circuit CCC in the third direction (Z-direction).

Hereinafter, a layout of the unit control circuit according to various example embodiments of the present disclosure is described.

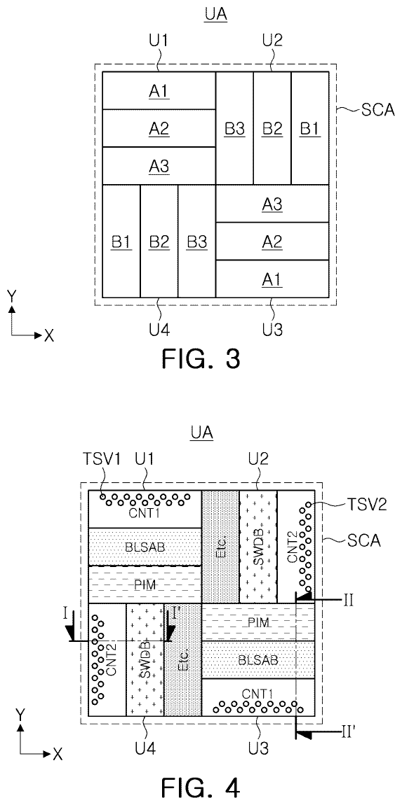

FIGS. 3 and 4 are views illustrating a layout of a unit control circuit according to an example embodiment of the present disclosure.

Referring to FIG. 3, one unit region UA may overlap one sub-cell region SCA in the third direction (Z-direction). The unit region UA may include four regions divided in the first direction (X-direction) and the second direction (Y-direction). The four regions may be defined as first to fourth regions U1 to U4 in a clockwise order based on the first region. That is, the four regions may include a first region U1, a second region U2 adjacent to the first region Ul in the first direction (X-direction), a third region U3 adjacent to the second region U2 in the second direction (Y-direction), and a fourth region U4 adjacent to the third region U3 in the first direction (X-direction), and the fourth region U4 may be adjacent to the first region U1 in the second direction (Y-direction).

Each of the first region U1 and the third region U3 may include a region A1, a region A2, and a region A3 adjacent to each other in the second direction (Y-direction). In an example embodiment, the region A1, the region A2, and the region A3 of the first region U1 and the third region U3 may be mutually disposed symmetrically.

The plurality of first through silicon vias (TSVs) connecting the bit line sense amplifier circuit and the bit lines, the bit line sense amplifier circuit, and the PIM circuit may be arranged in the region A1, the region A2, and the region A3. The order in which the plurality of first TSVs, the bit line sense amplifier circuit, and the PIM circuit are arranged in region A1, region A2, and region A3 is not limited.

Each of the second region U2 and the fourth region U4 may include a region B1, a region B2, and a region B3 adjacent to each other in the first direction (X-direction). In an example embodiment, the region B1, the region B2, and the region B3 of the second region U2 and the fourth region U4 may be mutually disposed symmetrically.

The plurality of second TSVs connecting the sub-word line driver circuit and the word lines, the sub-word line driver circuit, and other circuits may be arranged in the region B1, the region B2, and the region B3. The other circuits may include a power circuit and a row driver circuit. The order in which the plurality of second TSVs, the sub-word line driver circuit, and other circuits are arranged in the region B1, the region B2, and the region B3 is not limited.

Referring to FIG. 4, each of the first and third regions U1 and U3 may include a bit line contact region CNT1 in which a plurality of first TSVs (TSV1) are disposed, a bit line sense amplifier region BLSAB in which the bit line sense amplifier circuit is disposed, and a PIM circuit region PIM in which a PIM circuit is disposed. Additionally, each of the second and fourth regions U2 and U4 may include a word line contact region CNT2 in which a plurality of second TSVs (TSV2) are disposed, a sub-word line driver region SWDB in which the sub-word line driver circuit is disposed, and other regions (Etc.) in which other circuits are disposed.

In an example embodiment, the bit line contact regions CNT1 and the word line contact regions CNT2 may be disposed at an edge of the unit region UA. The bit line contact regions CNT1 may be connected to bit lines extending to an edge of the sub-cell region SCA through a plurality of first TSVs (TSV1), and the word line contact regions CNT2 may be connected to word lines extending to the edge of the sub-cell region SCA through the plurality of second TSVs (TSV2).

The plurality of first TSVs (TSV1) may be arranged in the first direction (X-direction) that is the same as a direction in which a plurality of bit lines are arranged in a cell array region SCA. Additionally, the plurality of first TSVs (TSV1) and the bit line sense amplifier circuit may be electrically connected, and the bit line sense amplifier circuit and the PIM circuit may be electrically connected.

The plurality of second TSVs (TSV2) may be arranged in the second direction (Y-direction) that is the same as the direction in which a plurality of word lines are arranged in the cell array region SCA. Additionally, the plurality of second TSVs (TSV2) and the sub-word line driver circuit may be electrically connected. Other circuits may be electrically connected to the sub-word line driver circuit, the bit line sense amplifier circuit, and the PIM circuit.

According to an embodiment of the present disclosure, in the unit region UA, the bit line contact region CNT1, the bit line sense amplifier region BLSAB, the PIM circuit region PIM, the word line contact region CNT2, the sub-word line driver region SWDB, and other circuit regions (Etc.) may be arranged in a windmill blade shape.

As the circuit regions are arranged in the windmill blade shape, the bit line sense amplifier circuit may be disposed adjacent to the plurality of bit lines, the sub-word line driver circuit is disposed adjacent to a plurality of word lines, and the PIM circuit may be disposed in the unit region UA overlapping the sub-cell region SCA. Accordingly, the PIM circuit may be disposed without increasing an area of the memory device.

Additionally, since the PIM circuit may be disposed adjacent to the bit line sense amplifier circuit, the PIM circuit may quickly obtain data sensed by the bit line sense amplifier, and quickly provide the bit line sense amplifier with data subjected to computational processing. Accordingly, the time required for the computational processing of data in the memory device can be shortened.

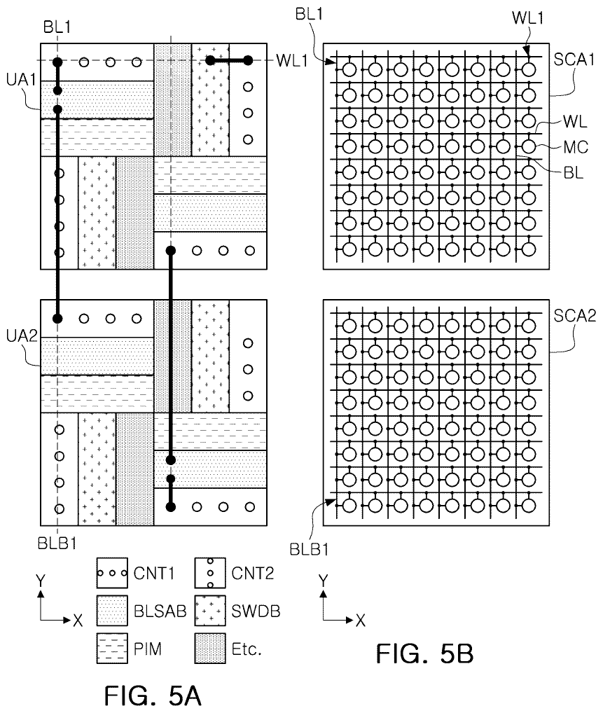

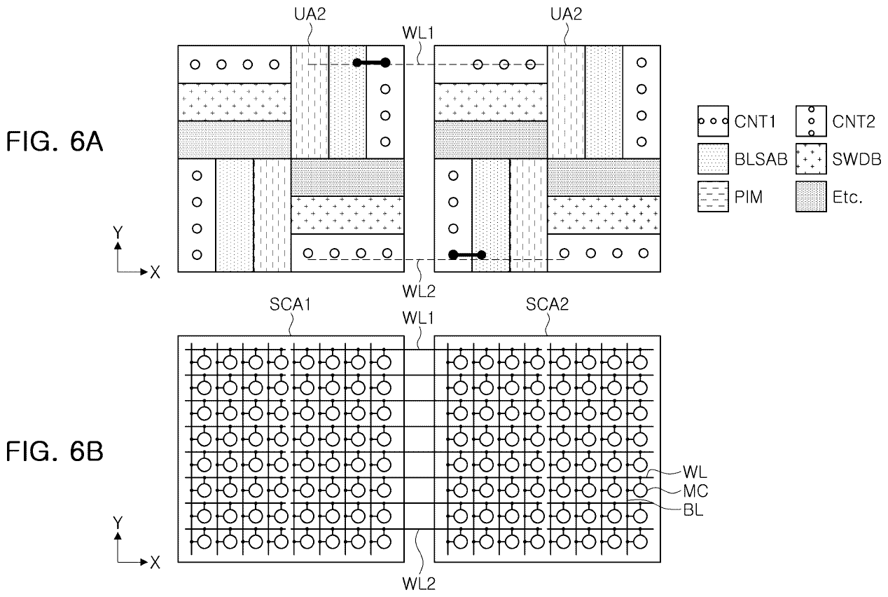

Hereinafter, with reference to FIGS. 5A to 6B, the connection structure of the word lines and the bit lines included in the sub-cell region SCA and the unit region UA will be described.

FIGS. 5A and 5B are views illustrating a unit region and a sub-cell region according to an example embodiment of the present disclosure.

FIG. 5A illustrates a first unit region UA1 and a second unit region UA2 adjacent to the first unit region UA1 in the second direction (Y-direction). The first unit region UA1 and the second unit region UA2 correspond to the unit region UA described with reference to FIG. 4, respectively.

FIG. 5B illustrates a first sub-cell region SCA1 and a second sub-cell region SCA2 adjacent to the first sub-cell region SCA1 in the second direction (Y-direction). As illustrated in FIG. 2, for example, the first sub-cell region SCA1 overlaps the first unit region UA1 in the third direction (Z-direction), and the second sub-cell region SCA2 overlaps the second unit region UA2 in the third direction (Z-direction). Each of the first sub-cell region SCA1 and the second sub-cell region SCA2 may include a plurality of word lines WL, a plurality of bit lines BL, and a plurality of memory cells MC connected to the plurality of word lines WL and the plurality of bit lines BL. The plurality of word lines WL may extend in the first direction (X-direction) and be arranged in the second direction (Y-direction). Additionally, the plurality of bit lines BL may extend in the second direction (Y-direction) and be arranged in the first direction (X-direction).

A connection relationship between the unit region and the sub-cell region according to an example embodiment of the present disclosure is described by taking as an example a first word line WL1 and a first bit line BL1 of the first sub-cell region SCA1, and a first complementary bit line BLB1 of the second sub-cell region SCA2. In FIG. 5A, exemplary locations of the first word line WL1, the first bit line BL1 and the first complementary bit line BLB1 are indicated by dashed lines, and examples of connections between the first word line WL1, the first bit line BL1 and the first complementary bit line BLB1 and the unit region UA are indicated by thick solid lines.

The bit line sense amplifier circuit may include a plurality of unit sense amplifier circuits. The unit sense amplifier circuit may be connected to a bit line pair. The bit line pair may include a bit line in which a voltage thereof is to be sensed, and a complementary bit line used to compare the voltage with the bit line. The unit sense amplifier circuit may sense and amplify a voltage level difference between the bit line and the complementary bit line to read data stored in a memory cell connected to the bit line, or store data in the memory cell based on the voltage level difference.

According to an example embodiment of the present disclosure, in order to sense a bit line voltage of the first sub-cell region SCA1, a complementary bit line of the second sub-cell region SCA2 adjacent to the first sub-cell region SCA1 in the second direction (Y-direction) may be used. For example, a first complementary bit line BLB1 may be used to sense a bit line voltage of the first bit line BL1. In an example embodiment, the first bit line BL1 may be connected to the unit sense amplifier circuit included in the bit line sense amplifier region BLSAB of the first unit region UA1 through a bit line contact region of the first unit region UA1. Additionally, the first complementary bit line BLB1 may be connected to the unit sense amplifier circuit through a bit line contact region of the second unit region UA2.

The sub-word line driver circuit may include a plurality of unit driver circuits. In an example embodiment, one unit driver circuit may be connected to one word line. For example, the first word line WL1 of the first sub-cell region SCA1 may be connected to the unit driver circuit included in the sub-word line driver region SWDB of the first unit region UA1 through a word line contact region of the first unit region UA1.

In an example embodiment, a pitch of the unit sense amplifier circuit in the first direction (X-direction) may be an integer multiple of a pitch of the memory cell in the first direction (X-direction). For example, unlike the memory cell including one cell transistor and one cell capacitor connected to one bit line and one word line, the unit sense amplifier circuit may include at least four transistors. Accordingly, the pitch of the unit sense amplifier circuits may be implemented as an integer multiple greater than 1 of the pitch of the memory cell, and the unit sense amplifier circuits may be arranged in the bit line sense amplifier region BLSAB in the first direction (X-direction) and the second direction (Y-direction).

A PIM circuit region PIM may include a plurality of unit PIM circuits, each of which is connected to one unit sense amplifier circuit and processes a data bit output from one bit line. A pitch of the unit PIM circuits in the first direction (X-direction) may be an integer multiple of a pitch of the memory cell in first direction (X-direction). As in the case of the unit sense amplifier circuit, the pitch of the unit PIM circuits may be implemented as an integer multiple greater than 1 of the pitch of the memory cell, and the unit PIM circuits may be arranged in the PIM circuit region PIM in the first direction (X-direction) and the second direction (Y-direction).

As described with reference to FIG. 2, adjacent sub-cell regions may include shared word lines.

FIG. 6A and FIG. 6B are views illustrating a core circuit region and a sub-cell region according to an example embodiment of the present disclosure.

FIG. 6A illustrates a first unit region UA1 and a second unit region UA2 adjacent to the first unit region UA1 in the first direction (X-direction). Each of the first unit region UA1 and the second unit region UA2 corresponds to the unit region UA described with reference to FIG. 4.

FIG. 6B illustrates a first sub-cell region SCA1 and a second sub-cell region SCA2 adjacent to the first sub-cell region SCA1 in the second direction (Y-direction). As illustrated in FIG. 2, for example, the first sub-cell region SCA1 overlaps the first unit region UA1 in the third direction (Z-direction), and the second sub-cell region SCA2 overlaps the second unit region UA2 in the third direction (Z-direction). Each of the first sub-cell region SCA1 and the second sub-cell region SCA2 may include a plurality of word lines WL, a plurality of bit lines BL, and a plurality of memory cells MC connected to the plurality of word lines WL and the plurality of bit lines BL.

At least some of the word lines of the first sub-cell region SCA1 and the word lines of the second sub-cell regions SCA2 may be shared word lines extending across the first sub-cell region SCA1 and the second sub-cell region SCA2. In FIG. 6B, a first word line WL1 and a second word line WL2, among the shared word lines, are indicated.

In FIG. 6A, positions corresponding to the first word line WL1 and the second word line WL2 are indicated by dashed lines. Additionally, a connection of the first word line WL1, the second word line WL2, the first unit region UA1, and the second unit region UA2 is indicated by thick solid lines.

The first word line WL1 may be connected to the sub-word line driver circuit of the first unit region UA1 through the word line contact region CNT2 included in the first unit region UA1. Additionally, the second word line WL2 may be connected to the sub-word line driver circuit included in the second unit region UA2 through the word line contact region CNT2 included in the second unit region UA2.

As described with reference to FIG. 5A and FIG. 5B, the bit line sense amplifier circuit included in the first unit region UA1 of FIG. 6A may be connected to the bit lines included in the first sub-cell array SCA1 and the complementary bit lines of the sub-cell array adjacent to the first sub-cell array SCA1 in the second direction (Y-direction).

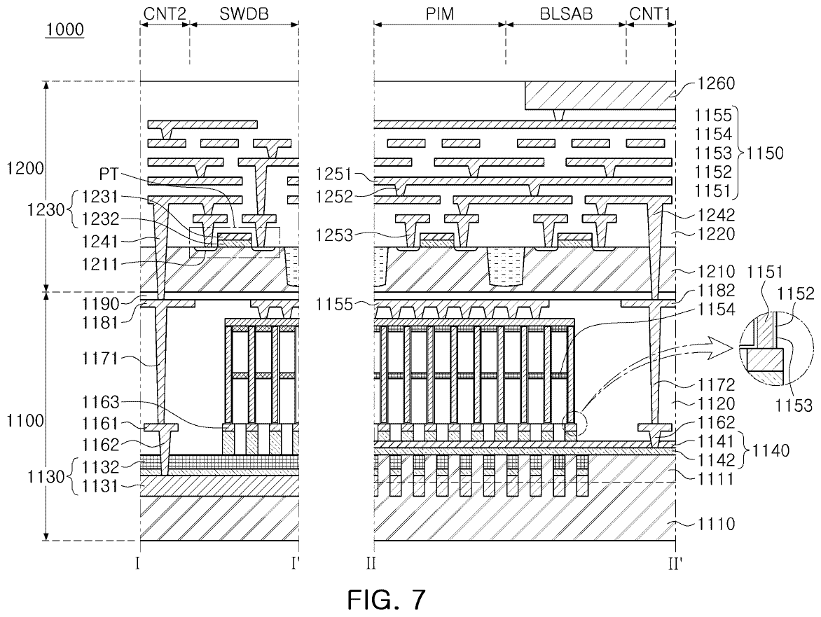

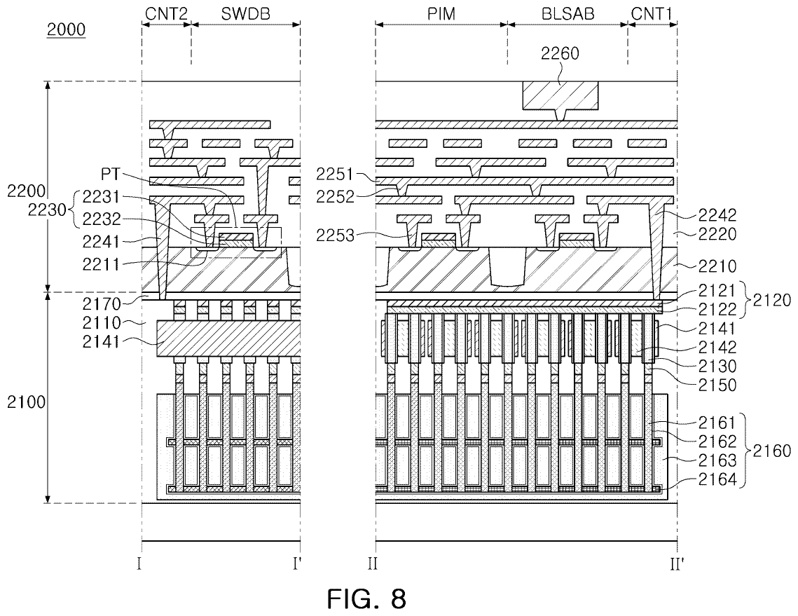

Hereinafter, the connection structure between the unit region and the sub-cell region according to an example embodiment of the present disclosure will be described in more detail with reference to FIGS. 7 and 8.

FIG. 7 is a view illustrating an example of a cross-section taken along lines I-I′ and II-II′ of FIG. 4.

A memory device 1000 may include a first semiconductor layer 1100 and a second semiconductor layer 1200. The first semiconductor layer 1100 may include a memory cell array including sub-cell blocks, and the second semiconductor layer 1200 may include a core control circuit including unit regions. The second semiconductor layer 1200 may be stacked on an upper portion of the first semiconductor layer 1100. That is, the memory device 1000 may have a PoC structure.

FIG. 7 illustrates a cross-section of a sub-cell region of the first semiconductor layer 1100, and illustrates cross-sections of a word line contact region CNT2, a sub-word line driver region SWDB, a PIM circuit region PIM, a bit line sense amplifier region BLSAB, and a bit line contact region CNT1 of the second semiconductor layer 1200.

The first semiconductor layer 1100 may include a first substrate 1110, an insulating layer 1120, a gate structure 1130, a bit line structure 1140, a memory cell structure 1150 including a cell capacitor CAP (1151, 1152, and 1153), conductive patterns 1161, 1162 and 1163, TSVs 1171 and 1172, pads 1181 and 1182, and a bonding layer 1190.

The first substrate 1110 may include a single crystal semiconductor material. The single crystal semiconductor material may include a group IV semiconductor, a group III-V compound semiconductor, or a group II-VI compound semiconductor, and may be, for example, a single crystal semiconductor including at least one of silicon, silicon carbide, germanium, or silicon-germanium. However, the present disclosure is not limited thereto, and the first substrate 1110 may include at least one of a polycrystalline semiconductor material layer, an oxide semiconductor material layer such as Indium Gallium Zinc Oxide (IGZO), or a two-dimensional material layer such as Molybdenum disulfide (MoS₂).

The first substrate 1110 may include an active region 1111. The active region 1111 may be doped with impurities and may provide a source region and a drain region of a cell transistor included in a memory cell.

In the sub-cell region, an active region 1111, a gate structure 1130 providing a word line, a bit line structure 1140 connected to at least a portion of the active region 1111, and a memory cell structure (e.g., memory cells) 1150 may be formed.

The gate structure 1130 may intersect the bit line structure 1140 and may be buried in the substrate 1110. For example, the cell transistor may have a buried channel array transistor (BCAT) structure. However, the present disclosure is not limited thereto, and the gate structure 1130 may be formed on the substrate 1110.

The gate structure 1130 may include a gate electrode layer 1131 and a capping layer 1132. The gate electrode layer 1131 may be formed of a conductive material such as a metal or a metal compound, and the capping layer 1132 may be formed of an insulating material such as silicon nitride. A gate insulating layer may be disposed between the gate electrode layer 1131 and the substrate 1110, and the gate insulating layer may be formed of silicon oxide, or the like.

The source region may be connected to the cell capacitor CAP through a contact pattern 1163. Additionally, the drain region may also be connected to the bit line structure 1140 through the contact pattern.

The bit line structure 1140 may be buried in the insulating layer 1120, and may include a bit line conductive layer 1141 and a bit line capping layer 1142. The bit line structure 1140 may further include a spacer layer surrounding the bit line conductive layer 1141 and the bit line capping layer 1142.

The memory cell structure 1150 may include a lower electrode layer 1151, a dielectric layer 1152, an upper electrode layer 1153, a support layer 1154, and a pad layer 1155. The lower electrode layer 1151, the dielectric layer 1152, and the upper electrode layer 1153 may be included in the cell capacitor CAP.

The lower electrode layer 1151 may be connected to the source region through the contact pattern 1163. The upper electrode layer 1153 may be connected to the pad layer 1155, and a ground voltage may be applied to the upper electrode layer 1153 by the pad layer 1155.

The cell capacitor CAP may extend in a direction perpendicular to the surface of the substrate 1110. The lower electrode layer 1151 may have a columnar shape as illustrated in FIG. 7, or may have a cylinder shape with a hollow center. The upper electrode layer 1153 may have a cylinder shape surrounding the lower electrode layer 1151, and the support layer 1154 may be disposed around the upper electrode layer 1153. However, the present disclosure is not limited thereto, and the upper electrode layer 1153 may be integrally formed to surround a plurality of lower electrode layers 1151.

The gate structure 1130 and the bit line structure 1140 may extend to a periphery of the memory cell structure 1150. The periphery of the memory cell structure 1150 may include a first TSV 1171 for electrically connecting the gate structures 1130 and the second semiconductor layer 1200, and a second TSV 1172 for electrically connecting the bit line structures 1140 to the second semiconductor layer 1200. The first TSV 1171 may be adjacent to the memory cell structure 1150 in the first direction (X-direction), and the second TSV 1172 may be adjacent to the memory cell structure 1150 in the second direction (Y-direction).

An interconnection pattern 1161 and a via pattern 1162 may be included between the first TSV 1171 and the gate structure 1130. Additionally, the interconnection pattern 1161 and the via pattern 1162 may be included between the second TSV 1172 and the bit line structure 1140. A first pad 1181 may be included between the first TSV 1171 and the bonding layer 1190, and a second pad 1182 may be included between the second TSV 1172 and the bonding layer 1190.

The insulating layer 1120 may cover the gate structure 1130, the bit line structure 1140, the memory cell structure 1150, the conductive patterns 1161, 1162, 1163 and 1164, and the TSVs 1171 and 1172, and may expose upper surfaces of the pads 1181 and 1182. The bonding layer 1190 may cover the upper surfaces of the pads 1181 and 1182 and an upper surface of the insulating layer 1120.

The second semiconductor layer 1200 may include a second substrate 1210, an insulating layer 1220, gate structures 1230, TSVs 1241 and 1242, conductive patterns 1251, 1252 and 1253, and pads 1260.

The gate structures 1230 may be disposed on an upper surface of the second substrate 1210 and may include a gate electrode layer 1231 and a gate insulating layer 1232. The gate structures 1230 may be disposed between active regions 1211 formed on the upper surface of the second substrate 1210. The active regions 1211 and the gate structures 1230 may form circuit elements PT. The circuit elements PT may be buried in the insulating layer 1220.

The TSVs 1241 and 1242 may penetrate through the insulating layer 1220, the second substrate 1210, and the bonding layer 1190 and may thus contact upper surfaces of the first pads 1181 and 1182. The TSVs 1241 and 1242 may include a third TSV 1241 for connecting the gate structure 1130 and the second semiconductor layer 1200 through the first TSV 1171, and a fourth TSV 1242 for connecting the bit line structure 1140 and the second semiconductor layer 1200 through the second TSV 1172.

The conductive patterns 1251, 1252 and 1253 for electrically connecting the circuit elements PT and the TSVs 1241 and 1242 may be included in upper portions of the circuit elements PT and the TSVs 1241 and 1242. The conductive patterns 1251, 1252 and 1253 may include interconnection patterns 1251, via patterns 1252, and contact patterns 1253. The circuit elements PT may be connected to the conductive patterns 1251, 1252 and 1253 to form a bit line sense amplifier circuit, a sub-word line driver circuit, a PIM circuit, and other circuits.

The pads 1260 may output signals of the memory device 1000 to the outside, or may receive signals from the outside. For example, data signals output from the bit line sense amplifier circuits may be output to the outside through the pads 1260, or the data signals received through the pads 1260 may be provided to the bit line sense amplifier circuits.

According to an example embodiment of the present disclosure, the PIM circuit may be disposed adjacent to a data transmission path including a bit line sense amplifier circuit, thereby increasing energy efficiency for data operation processing.

The insulating layer 1220 may cover the upper surface of the second substrate 1210, the gate structures 1230, the TSVs 1241 and 1242, and the conductive patterns 1250, and may expose upper surfaces of the pads 1260.

FIG. 8 is a view illustrating an example of a cross-section taken along lines I-I′ and II-II′ of FIG. 4.

A memory device 2000 may include a first semiconductor layer 2100 and a second semiconductor layer 2200. The first semiconductor layer 2100 may include a memory cell array including sub-cell blocks, and the second semiconductor layer 2200 may include a core control circuit including unit regions. The second semiconductor layer 2200 may be stacked on an upper portion of the first semiconductor layer 2100. That is, the memory device 2000 may have a PoC structure.

Unlike the cell transistor having a buried channel array transistor (BCAT) structure in the example of FIG. 7, the cell transistor in the example of FIG. 8 may have a vertical channel transistor (VCT) structure.

The first semiconductor layer 2100 may include an insulating layer 2110, bit line structures 2120, channel structures 2130, gate structures 2141, back gate structures 2142, cell contacts 2150, capacitor structures 2160, and a bonding layer 2170.

The bit line structures 2120 may extend in the second direction (Y-direction), and may be spaced apart from each other and extend in parallel in the first direction (X-direction). The bit line structures 2120 may be electrically connected to the channel structures 2130. The bit line structures 2120 may correspond to the bit line BL illustrated in FIG. 5B and FIG. 6B.

The bit line structures 2120 may include doped polysilicon, a metal, conductive metal nitride, a metal-semiconductor compound, conductive metal oxide, conductive graphene, carbon nanotubes, or combinations thereof. In an example embodiment, the bit line structures 2120 may include first conductive patterns 2121 and second conductive patterns 2122 which are stacked. However, the present disclosure is not limited thereto, and the number and thickness of layers forming the bit line structures 2120 may be variously changed.

The back gate structures 2142 may intersect the bit line structures 2120. For example, the back gate structures 2142 may extend in the first direction (X-direction), and may be spaced apart from each other in the second direction (Y-direction). The back gate structures 2142 may perform a role of removing electric charges trapped in the channel structures 2130. The channel structures 2130 may be floating bodies, and the back gate structures 2142 may be structures for preventing performance degradation of the memory device 2000 due to a floating body effect of the channel structures 2130.

The channel structures 2130 may extend from a lower surface of the bit line structures 2120 in the third direction (Z-direction), perpendicular to a substrate of the memory device 2000. The channel structures 2130 may be disposed on side surfaces of the back gate structures 2142. The channel structures 2130 may be spaced apart from each other in the first direction (X-direction) and the second direction (Y-direction). Each of the channel structures 2130 may include a drain region in contact with the bit line structure 2120, a source region connected to the cell contact 2150, and a channel region between the drain region and the source region.

In an example embodiment, the channel structures 2130 may include a single crystal semiconductor material. The single crystal semiconductor material may include a group IV semiconductor, a group III-V compound semiconductor, or a group II-VI compound semiconductor, and may be, for example, a single crystal semiconductor including at least one of silicon, silicon carbide, germanium, or silicon-germanium. However, the present disclosure is not limited thereto, and the channel structures 2130 may also include at least one of a polycrystalline semiconductor material layer, an oxide semiconductor material layer such as Indium Gallium Zinc Oxide (IGZO), or a two-dimensional material layer such as Molybdenum disulfide (MoS₂).

The gate structures 2141 may be disposed on both sides of the back gate structures 2142. The channel structures 2130 may be disposed between the gate structures 2141 and the back gate structures 2142. The gate structures 2141 may extend in the first direction (X-direction) and may be spaced apart from each other in the second direction (Y-direction). The gate structures 2141 may correspond to the word lines WL of FIG. 5B and FIG. 6B.

The gate structures 2141 may be formed of the same material as the back gate structures 2142. However, the present disclosure is not limited thereto.

The cell contacts 2150 may be in contact with lower portions of the channel structures 2130, and the capacitor structures 2160 may be in contact with lower portions of the cell contacts 2150.

The cell contacts 2150 may include conductive materials, for example, doped single crystal silicon, doped polycrystalline silicon, a metal, a conductive metal nitride, a metal-semiconductor compound, a conductive metal oxide, conductive graphene, carbon nanotubes, or combinations thereof.

Each of the capacitor structures 2160 may include a first electrode layer 2161, a dielectric layer 2162, and a second electrode layer 2163. The first electrode layer 2161 may be in contact with the cell contacts 2150. The first electrode layer 2161 may have a columnar shape as illustrated in FIG. 8, or a cylindrical shape with a hollow center. The dielectric layer 2162 may include a high dielectric, silicon oxide, silicon nitride, silicon oxynitride, or combinations thereof. The third electrode layer 2163 may be formed to have a structure surrounding the first electrode layer 2161 and the dielectric layer 2162. In an example embodiment, the capacitor structures 2160 may further include a support layer 2164 surrounding the first electrode layers 2161.

The first semiconductor layer 2100 may surround the channel structure 2130, the gate structure 2141, the back gate structure 2142, the cell contact 2150 and the capacitor structure 2160, and may include an insulating layer 2110 exposing an upper surface of the bit line structure 2120, and a bonding layer 2170 covering upper surfaces of the insulating layer 2110 and the bit line structure 2120.

Referring to FIG. 8, the first semiconductor layer 2100 may not include a substrate. In an example embodiment, the first semiconductor layer 2100 may be formed by sequentially forming the bit line structures 2120, the channel structures 2130, the gate structures 2141, the back gate structures 2142, the cell contacts 2150, and the capacitor structures 2160 on the substrate, forming a memory cell array structure by forming a first insulating layer 2110, removing the substrate, and flipping the memory cell array structure.

The second semiconductor layer 2200 may include a substrate 2210, an insulating layer 2220, gate structures 2230, TSVs 2241 and 2241, conductive patterns 2251, 2252 and 2253, and pads 2260.

The substrate 2210, the insulating layer 2220, the gate structures 2230, the TSVs 2241 and 2242, the conductive patterns 2251, 2252 and 2253 and the pads 2260 may correspond to the second substrate 1210, the insulating layer 1220, the gate structures 1230, the TSVs 1241 and 1242, the conductive patterns 1251, 1252 and 1253 and the pads 1260 described with reference to FIG. 7.

For example, conductive patterns 2251, 2252 and 2253 and circuit elements PT, which include active regions 2211 and the gate structures 2230, may form a bit line sense amplifier circuit, a sub-word line driver circuit, a PIM circuit, and other circuits. Additionally, the first TSVs 1241 may connect the gate structures 2141 and the sub-word line driver circuit, and the second TSVs 1242 may connect the bit line structures 2130 and the bit line sense amplifier circuit. The pad 2260 may output a signal of the memory device 2000 to the outside or may receive a signal from the outside.

Referring to FIGS. 7 and 8, an example embodiment of the present disclosure has been described as an example in which a lower surface of the second semiconductor layer 1200 is bonded to an upper surface of the first semiconductor layer 1100 to overlap the sub-cell region and the unit region and to connect the bit lines to the word lines. However, the present disclosure is not limited thereto. For example, a pad formed on the upper surface of the first semiconductor layer and a pad formed on the upper surface of the second semiconductor layer may be bonded to each other, so that the sub-cell region and the unit region may overlap each other, and the bit lines and word lines may be connected to the circuits of the unit region.

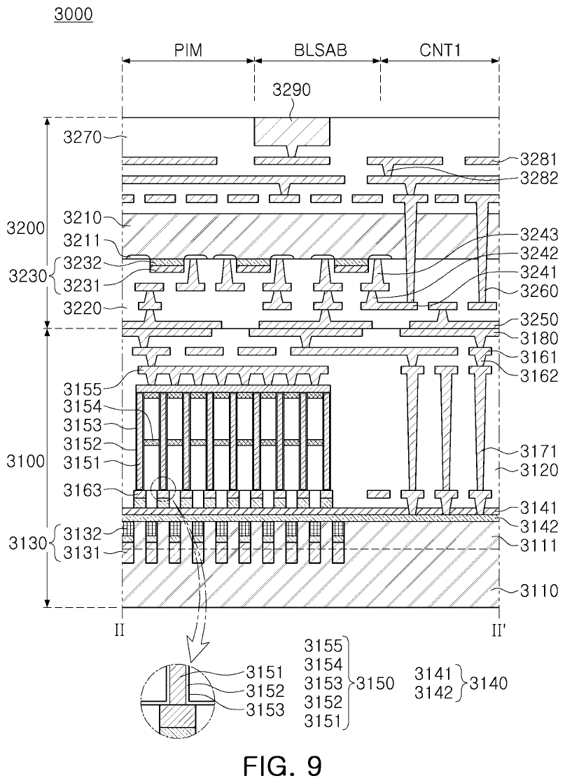

FIG. 9 is a view illustrating an example of a cross-section taken along line II-II′ of FIG. 4.

A memory device 3000 may include a first semiconductor layer 3100 and a second semiconductor layer 3200. The first semiconductor layer 3100 may include a memory cell array including sub-cell blocks, and the second semiconductor layer 3200 may include a core control circuit including unit regions.

FIG. 9 illustrates a cross-section of a portion of a sub-cell region of the first semiconductor layer 3100, and illustrates cross-sections of a PIM circuit region PIM, a bit line sense amplifier region BLSAB, and a bit line contact region CNT1 of the second semiconductor layer 3200.

The first semiconductor layer 3100 may include a first substrate 3110, an insulating layer 3120, a gate structure 3130, a bit line structure 3140, a capacitor structure 3150, conductive patterns 3161, 3162 and 3163, TSVs 3171, and pads 3180.

The first semiconductor layer 3100 may have a structure similar to the first semiconductor layer 1100 described with reference to FIG. 7, except that the first semiconductor layer 3100 does not include a bonding layer. The first substrate 3110, the insulating layer 3120, the gate structure 3130, the bit line structure 3140, the capacitor structure 3150, the conductive patterns 3161 and 3162 and the TSVs 3171 of the first semiconductor layer 3100 may correspond to the first substrate 1110, the insulating layer 1120, the gate structure 1130, the bit line structure 1140, the capacitor structure 1150, the conductive patterns 1161 and 1162 and the first TSVs 1171 and the pads 1181 of the first semiconductor layer 1100 of FIG. 7. For example, the capacitor structure 3150 may include a lower electrode layer 3151, a dielectric layer 3152, an upper electrode layer 3153, a support layer 3154, and a pad layer 3155.

The second semiconductor layer 3200 may include a second substrate 3210, a first insulating layer 3220, gate structures 3230, first conductive patterns 3241, 3242 and 3243, a bonding pad 3250, TSVs 3260, a second insulating layer 3270, second conductive patterns 3281 and 3282, and input/output pads 3290.

The gate structures 3230 may be disposed on one surface of the second substrate 3210, and may include a gate electrode layer 3231 and a gate insulating layer 3232. The gate structures 3230 may be disposed between active regions 3211 formed on one surface of the second substrate 3210. The active regions 3211 and the gate structures 3230 may be included in circuit elements PT. In the second substrate 3210, a surface on which the circuit elements PT are formed may be referred to as an upper surface, and a surface opposite to the upper surface may be referred to as the lower surface.

An upper portion of the circuit elements PT may include first interconnection patterns 3241, first via patterns 3242, and first contact patterns 3243, for the purpose of electrically connecting the circuit elements PT. The circuit elements PT may be connected to the first interconnection patterns 3241, the first via patterns 3242, and the first contact patterns 3243, thus forming a bit line sense amplifier circuit, a sub-word line driver circuit, a PIM circuit, and other circuits. In the example of FIG. 7, a PIM circuit region PIM and a bit line sense amplifier region BLSAB are illustrated.

Bonding pads 3250 may be formed on upper portions of the first interconnection patterns 3241. An insulating layer 3220 covers an upper surface of the second substrate 3210, the gate structures 3230, and the first conductive patterns 3241 3242 and 3243, and may expose upper surfaces of the bonding pads 3250.

The first semiconductor layer 3100 and the second semiconductor layer 3200 may be bonded to each other in a direction in which an upper surface of the first substrate 3110 and an upper surface of the second substrate 3210 face each other. The insulating layer 3120 and the insulating layer 3220 may be bonded to each other, and the bonding pads 3180 and the bonding pads 3250 may be bonded to each other, so that the first semiconductor layer 3100 and the second semiconductor layer 3200 may be electrically connected to each other. For example, the bonding pads 3180 and the bonding pads 3250 may include a conductive material such as copper (Cu).

The second semiconductor layer 3200 may further include the second insulating layer 3270, second interconnection patterns 3281, second via patterns 3282, and input/output pads 3290, which are formed on a lower surface of the second substrate 3210. The second interconnection patterns 3281 may be connected to the first interconnection patterns 3241 to electrically connect the circuit elements PT. The second interconnection patterns 3281 may be connected to the first conductive patterns 3241 through the TSVs 3260 penetrating through the second insulating layer 3270, the second substrate 3210 and the first insulating layer 3220.

In an example embodiment, the TSVs 3260 may be disposed in the bit line contact region CNT1 adjacent to the bit line sense amplifier region BLSAB. However, the present disclosure is not limited thereto. The bit line sense amplifier region BLSAB and the bit line contact region CNT1 may not be strictly distinguished from each other, and the TSVs 3260 may be disposed in the bit line sense amplifier region BLSAB.

An input/output pad 3290 may output a signal of the memory device 3000 to the outside or may receive a signal from the outside.

With reference to FIGS. 4 to 9, example embodiments of the present disclosure have been described as an example in which the unit region includes the bit line contact region CNT1 separated from the bit line sense amplifier region BLSAB and includes the word line contact region CNT2 separated from the sub-word line driver region SWDB. However, the present disclosure is not limited thereto.

According to an example embodiment of the present disclosure, a structure connecting the bit lines and the bit line sense amplifier circuits may overlap the bit line sense amplifier region BLSAB, and a structure connecting the word lines and the sub-word line driver circuits may overlap the sub-word line driver region SWDB.

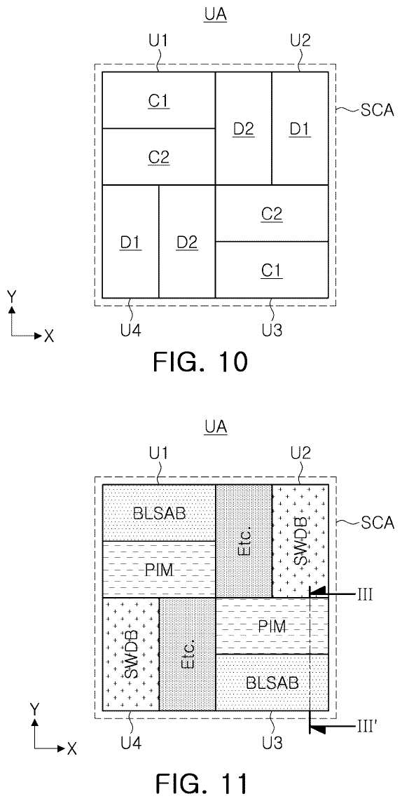

Hereinafter, with reference to FIGS. 10 to 13, examples of a connection structure of the unit region and the sub cell region according to an example embodiment of the present disclosure will be described in detail.

FIGS. 10 and 11 are views illustrating a layout of a unit control circuit according to an example embodiment of the present disclosure.

Referring to FIG. 10, one unit region UA may overlap one sub cell region SCA in the third direction (Z-direction). The unit region UA may include four regions divided in the first direction (X-direction) and the second direction (Y-direction). The four regions may be defined as first to fourth regions U1 to U4 in a clockwise order based on the first region.

Each of the first region U1 and the third region U3 may include region C1 and region C2 adjacent to each other in the second direction (Y-direction). A bit line sense amplifier circuit and a PIM circuit may be arranged in region C1 and region C2. The order in which the bit line sense amplifier circuit and the PIM circuit are disposed in region C1 and region C2 is not limited.

Each of the second region U2 and the fourth region U4 may include region D1 and region D2 adjacent to each other in the first direction (X-direction). A sub-word line driver circuit and other circuits may be disposed in region D1 and region D2. The other circuits may include a power circuit and a row driver circuit. The order in which the sub-word line driver circuit and other circuits are disposed in region D1 and region D2 is not limited.

Referring to FIG. 11, each of the first and third regions U1 and U3 may include a bit line sense amplifier region BLSAB and a PIM circuit region PIM in which a PIM circuit is disposed. Additionally, each of the second and fourth regions U2 and U4 may include a sub-word line driver region SWDB and other regions (Etc.). In an example embodiment, the bit line sense amplifier region BLSAB and the sub-word line driver region (SWDB) may be disposed at an edge of the unit region UA.

A connection structure connecting the bit lines and the bit line sense amplifier circuit may overlap the bit line sense amplifier region BLSAB, and a connection structure connecting the word lines and the sub-word line driver circuit may overlap the sub-word line driver region SWDB.

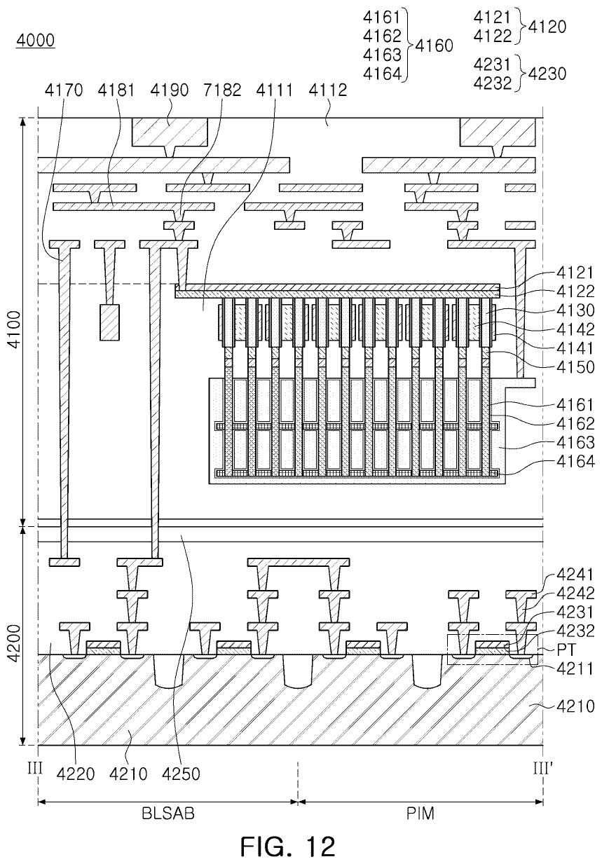

FIG. 12 is a view illustrating an example of a cross-section taken along line III-III′ of FIG. 11.

A memory device 4000 may include a first semiconductor layer 4100 and a second semiconductor layer 4200. The first semiconductor layer 4100 may include a memory cell array including sub-cell blocks, and the second semiconductor layer 4200 may include a core control circuit including unit regions. The first semiconductor layer 4100 may be stacked on an upper portion of the second semiconductor layer 4200. That is, the memory device 4000 may have a CoP structure.

FIG. 12 illustrates a cross-section of a portion of a sub-cell region of the first semiconductor layer 4100 and illustrates a cross-section of a bit line sense amplifier region BLSAB and a PIM circuit region PIM of the second semiconductor layer 4200.

The first semiconductor layer 4100 may include insulating layers 4111 and 4112, bit line structures 4120, channel structures 4130, gate structures 4141, back gate structures 4142, cell contacts 4150, capacitor structures 4160, TSVs 4170, conductive patterns 4181 and 4182, and input/output pads 4190.

Sub-cell blocks of the first semiconductor layer 4100 may have a structure similar to the sub-cell blocks included in the first semiconductor layer 2100 of FIG. 8. For example, the first insulating layer 4111, the bit line structure 4120, the channel structure 4130, the gate structure 4141, the back gate structure 4142, the cell contact 4150, and the capacitor structure 4160 may correspond to the insulating layer 2110, the bit line structure 2120, the channel structure 2130, the gate structure 2141, the back gate structure 2142, the cell contact 2150, and the capacitor structure 2160 of FIG. 8. For example, the capacitor structure 4160 may include the first electrode 4161, the dielectric layer 4162, the second electrode 4163, and the support layer 4164.

The second semiconductor layer 4200 may include a substrate 4210, an insulating layer 4220, gate structures 4230, conductive patterns 4241, via patterns 4242, contact patterns 4243, and a bonding layer 4250.

The gate structures 4230 may be disposed on an upper surface of the substrate 4210, and may include a gate electrode layer 4231 and a gate insulating layer 4232. The gate structures 4230 may be disposed between active regions 4211 formed on the upper surface of the substrate 4210. The active regions 4211 and the gate structures 4230 may be included in circuit elements PT.

An upper portion of the circuit elements PT may include conductive patterns 4241, via patterns 4242, and contact patterns 4243, for the purpose of electrically connecting the circuit elements PT. The circuit elements PT may be connected by the conductive patterns 4241, the via patterns 4242, and the contact patterns 4243, thereby forming a bit line sense amplifier circuit and a PIM circuit.

The insulating layer 4220 may cover the circuit elements PT and the conductive patterns 4241, the via patterns 4242 and the contact patterns 4243. A bonding layer 4250 may be formed on an upper surface of the insulating layer 4220.

A structure for connecting the circuit elements PT and the sub-cell blocks may overlap the bit line sense amplifier region BLSAB. For example, the connection structure may be disposed in the first insulating layer 4111 and the second insulating layer 4112. The TSVs 4170 may be disposed in the first insulating layer 4111 and the second insulating layer 4112, and the interconnection patterns 4181 and the via patterns 4182 may be disposed in the second insulating layer 4112.

The TSVs 4170 may penetrate through the second insulating layer 4112, the first insulating layer 4111, the bonding layer 4250, and the insulating layer 4220 and may thus connect the interconnection patterns 4181 to the interconnection patterns 4241.

The pads 4190 may be connected to the conductive patterns 4171, and upper surfaces thereof may be exposed to the second insulating layer 4112. The pad 4190 may output a signal of the memory device 4000 to the outside or may receive a signal from the outside.

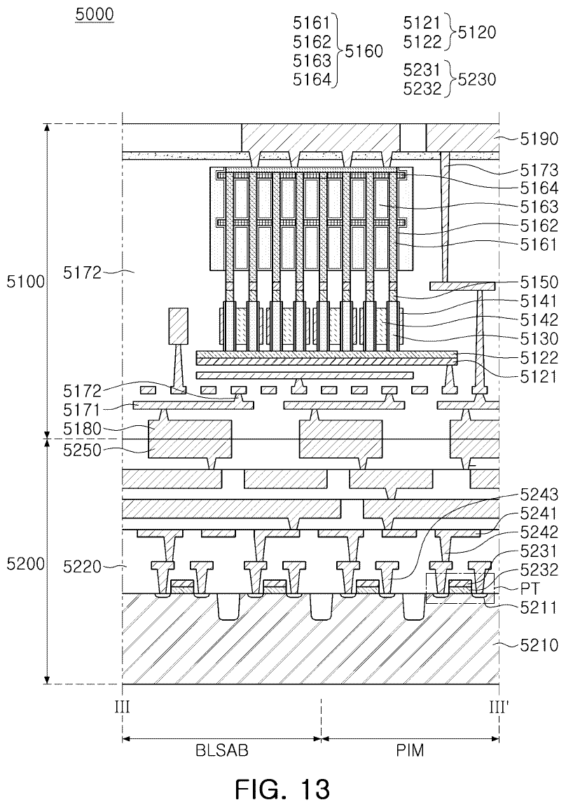

FIG. 13 is a view illustrating an example of a cross-section taken along line III-III′ of FIG. 11.

A memory device 5000 may include a first semiconductor layer 5100 and a second semiconductor layer 5200. The first semiconductor layer 5100 may include a memory cell array including sub-cell blocks, and the second semiconductor layer 5200 may include a core control circuit including unit regions. The first semiconductor layer 5100 may be stacked on an upper portion of the second semiconductor layer 5200. That is, the memory device 5000 may have a CoP structure.

The sub-cell blocks of the first semiconductor layer 5100 may have a structure similar to the sub-cell blocks included in the first semiconductor layer 2100 of FIG. 8. For example, an insulating layer 5110, a bit line structure 5120, a channel structure 5130, a gate structure 5141, a back gate structure 5142, a cell contact 5150, and a capacitor structure 5160 may correspond to the insulating layer 2110, the bit line structure 2120, the channel structure 2130, the gate structure 2141, the back gate structure 2142, the cell contact 2150, and the capacitor structure 2160 of FIG. 8. For example, the capacitor structure 5160 may include a first electrode 5161, a dielectric layer 5162, a second electrode 5163, and a support layer 5164.

The second semiconductor layer 5200 may include a substrate 5210, an insulating layer 5220, gate structures 5230, conductive patterns 5241, via patterns 5242, contact patterns 5243, and bonding pads 5250. Circuit elements PT comprised of active regions 5211 and the gate structures 5230 formed on an upper surface of the substrate 5210, and the conductive patterns 5241, the via patterns 5242 and the contact patterns 5243 may be included in a bit line sense amplifier circuit and a PIM circuit.

The first semiconductor layer 5100 may further include conductive patterns 5171, via patterns 5172, TSVs 5173, bonding pads 5180, and input/output pads 5190. The bonding pads 5180 may be bonded to the bonding pads 5250, so that the circuit elements PT may be connected to the bit line structures 5120 and the gate structures 5141, and the circuit elements PT may transmit or receive signals to or from the outside.

The structure of the memory device according to an example embodiment of the present disclosure is not limited to the structures described with reference to FIGS. 7, 8, 9, 12 and 13. For example, a cell transistor included in a first semiconductor chip is not limited to BCAT and VCT, and may have a 3D-stacked structure. Additionally, the structure of the circuit element PT is not limited to a planar Field Effect Transistor (FET) structure as illustrated in FIGS. 7, 8, 9, 12 and 13, and may have various structures such as FinFET, GAAFET and MBCFET.

Referring to FIGS. 4 to 13, example embodiments of the present disclosure have been described by taking as an example a case in which one unit region overlaps one sub-cell region in the third direction (Z-direction). However, the present disclosure is not limited thereto. According to an example embodiment of the present disclosure, one unit region may overlap a plurality of adjacent sub-cell regions.

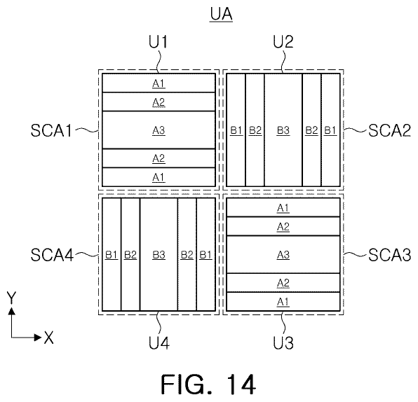

Hereinafter, with reference to FIGS. 14 to 26, an arrangement structure of the unit region according to various example embodiments of the present disclosure and a connection structure of a unit region and a sub-cell region will be described.

FIG. 14 is a view illustrating a core circuit region according to an example embodiment of the present disclosure.

Referring to FIG. 14, one unit region UA may include four regions divided in the first direction (X-direction) and the second direction (Y-direction). The four regions may be defined as first to fourth regions U1 to U4 in a clockwise order based on the first region U1.

In an example of FIG. 14, one unit region UA may overlap, in the third direction (Z-direction), four sub-cell regions SCA adjacent to each other in the first direction (X-direction) and the second direction (Y-direction). Each of the first to fourth areas U1 to U4 may overlap one sub-cell region SCA in the third direction (Z-direction). For example, first to fourth areas U1 to U4 may overlap first to fourth areas SCA1 to SCA4, respectively.

Each of the first region U1 and the third region U3 may include a region A3, two regions A2 each adjacent to the region A3 in the second direction (Y-direction), and two regions A1 respectively disposed adjacent to each of the two region A2 in the second direction (Y-direction). A bit line contact region may be disposed in each of the two regions A1, a bit line sense amplifier circuit may be disposed in each of the two regions A2, and a PIM circuit may be disposed in the region A3. The order in which the bit line contact region, the bit line sense amplifier circuit, and the PIM circuit are disposed in each of the two regions A1, each of the two regions A2, and the region A3 is not limited.

Each of the second region U2 and the fourth region U4 may include a region B3, two regions B2 respectively disposed adjacent to the region B3 in the first direction (X-direction), and two regions B1 respectively disposed adjacent to each of the two regions B2 in the first direction (X-direction). A word line contact region may be disposed in each of the two regions B1, a sub-word line driver circuit may be disposed in each of the two regions B2, and other circuits may be disposed in the region B3. The order in which the word line contact region, the sub-word line driver circuit, and other circuits are arranged in each of the two B1 regions, each of the two B2 regions, and the B3 region is not limited.

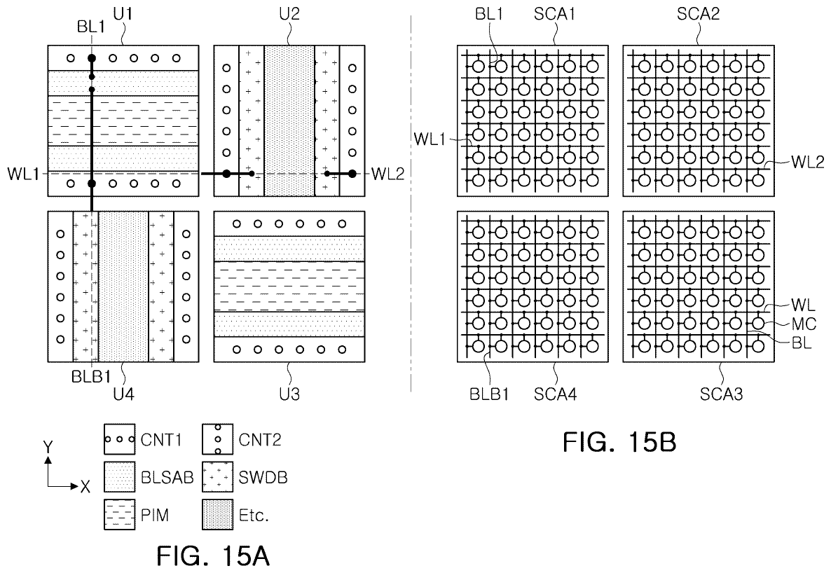

FIGS. 15A and 15B are views illustrating a core circuit region and a sub-cell region according to an example embodiment of the present disclosure.

FIG. 15A illustrates a unit region UA, which includes include four regions (i.e., first to fourth regions U1 to U4) divided in the first direction (X-direction) and the second direction (Y-direction). FIG. 15B illustrates a plurality of sub-cell regions SCA1 to SCA4. The unit region UA of FIG. 15A corresponds to the unit region UA described with reference to FIG. 14.

In the third direction (Z-direction), the first region U1 may overlap the first sub-cell region SCA1, the second region U2 may overlap the second sub-cell region SCA2, the third region U3 may overlap the third sub-cell region SCA3, and the fourth region U4 may overlap the fourth sub-cell region SCA4. Each of a plurality of sub-cell regions SCA1 to SCA4 may include a plurality of word lines WLs extending in the first direction (X-direction), a plurality of bit lines BLs extending in the second direction (Y-direction), and a plurality of memory cells MCs.

A connection structure of a unit region and sub-cell regions according to an example embodiment of the present disclosure will be described by taking a first word line WL1 and a first bit line BL1 in the first sub-cell region SCA1, a second word line WL2 in the second sub-cell region SCA2, and a first complementary bit line BLB1 in the fourth sub-cell region SCA4 as an example.

In FIG. 15A, exemplary positions of the first word line WL1, the second word line WL2, the first bit line BL1, and the first complementary bit line BLB 1 are indicated by dashed lines, and a connection between the first word line WL1, the second word line WL2, the first bit line BL1, and the first complementary bit line BLB1 and the unit region UA is indicated by thick solid lines.

According to an example embodiment of the present disclosure, in order sense a bit line voltage in the first sub-cell region SCA1, a complementary bit line of the fourth sub-cell region SCA4 may be used.

In an example embodiment, a bit line of the fourth sub-cell region SCA4 may extend to a bit line contact region CNT1 of the first unit region U1. The bit line of the fourth sub-cell region SCA4 may be connected to a bit line sense amplifier region BLBA of the first region U1 through a bit line contact region CNT1 of the first region U1. Similarly, a bit line of the second sub-cell region SCA2 may extend to a bit line contact region CNT1 of the third unit region U3.

According to an example embodiment of the present disclosure, the second word line WL2 of the second sub-cell region SCA2 may be connected to the sub-word line driver region SWDB of the second region U2. Additionally, the first word line WL1 of the first sub-cell region SCA1 may be connected to the sub-word line driver region SWDB of the second region U2 adjacent to the first region U1.

In an example embodiment, the word lines of the first sub-cell region SCA1 may extend to a word line contact region CNT2 of the second region U2. The word lines of the first sub-cell region SCA1 may be connected to the sub-word line driver region SWDB through the word line contact region CNT2 of the second region U2. Similarly, the word lines of the third sub-cell region SCA3 may extend to the word line contact region CNT2 of the fourth region U4, and the word lines may be connected to the sub-word line driver region SWDB of the fourth region U4.

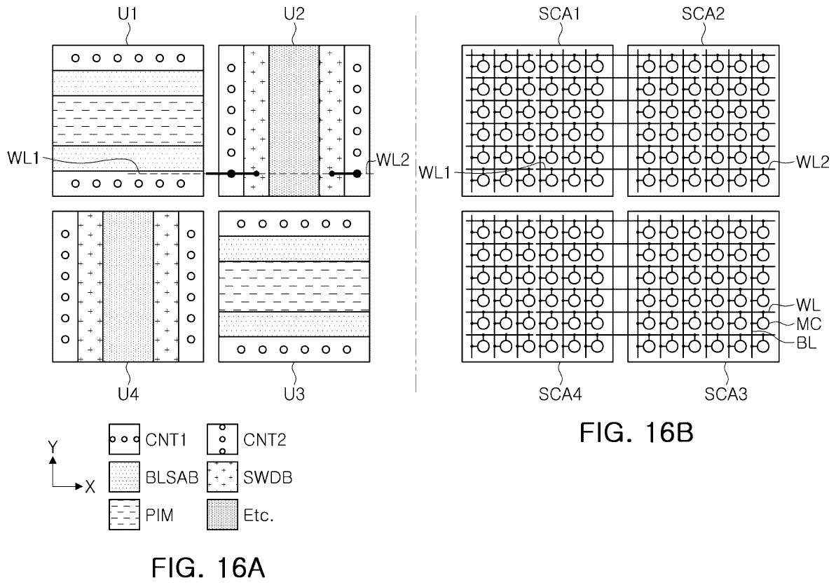

FIGS. 16A and 16B are views illustrating a core circuit region and a sub-cell region according to an example embodiment of the present disclosure.

A unit region UA of FIG. 16A may have the same structure as the unit region UA of FIG. 15A. Additionally, a plurality of sub-cell regions SCA1 to SCA4 of FIG. 16B may have a structure similar to that of the plurality of sub-cell regions SCA1 to SCA4 of FIG. 15B. However, unlike the plurality of sub-cell regions SCA1 to SCA4 of FIG. 15B, first and second sub-cell regions SCA1 and SCA2 of FIG. 16B may have a shared word line, and third and fourth sub-cell regions SCA3 and SCA4 of FIG. 16B may have a shared word line.

FIG. 16B illustrates a first word line WL1, one of the shared word lines of the first and second sub-cell regions SCA1 and SCA2. Additionally, FIG. 16B illustrates a second word line WL2 of the second sub-cell region SCA2. The first word line WL1 and the second word line WL2 may be disconnected from each other. For example, the second word line WL2 may be a shared word line extending to another sub-cell region adjacent to the second sub-cell region SCA2 in the first direction (X-direction).

Additionally, in FIG. 16A, a position corresponding to the first word line WL1 is indicated by dashed lines. A connection between the first word line WL1 and the unit region UA is indicated by thick solid lines.

According to an example embodiment of the present disclosure, the first word line WL1 may be connected to the sub-word line driver region SWDB of the second region U2 through the word line contact region CNT2 included in the second region U2 in which the first word lines WL1 overlap each other. The second word line WL2 may be connected to the sub-word line driver region SWDB of the second region U2 through the word line contact region CNT2 included in the second region U2 where the second word line WL2 overlaps each other.

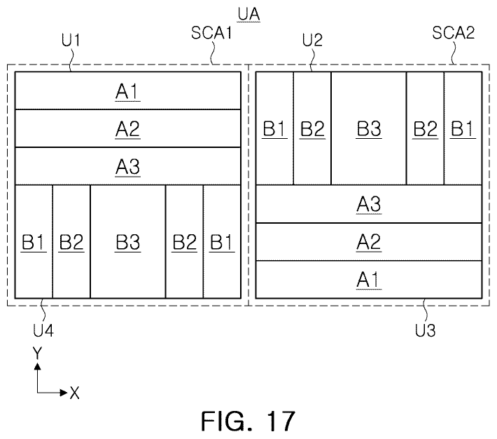

FIG. 17 is a view illustrating a core circuit region according to an example embodiment of the present disclosure.

Referring to FIG. 17, one unit region UA may include four regions divided in the first direction (X-direction) and the second direction (Y-direction). The four regions may be defined as first to fourth regions U1 to U4 in a clockwise order based on a first region U1.

In an example of FIG. 17, one unit region UA may overlap, in the third direction (Z-direction), two sub-cell regions SCA1 and SCA2 adjacent to each other in the first direction (X-direction). The first region U1 and the fourth region U4 may overlap the first sub-cell region SCA1, and the second region U2 and the third region U3 may overlap the second sub-cell region SCA2.

Each of the first region U1 and the third region U3 may include a region A1, a region A2, and a region A3, which are disposed adjacent to each other in the second direction (Y-direction). A bit line contact region, a bit line sense amplifier circuit, and a PIM circuit may be disposed in the region A1, the region A2, and the region A3. The order in which the bit line contact region, the bit line sense amplifier circuit, and the PIM circuit are disposed in the region A1, the region A2 and the region A3 is not limited.

Each of the second region U2 and the fourth region U4 may include a region B3, two regions B2 respectively disposed adjacent to the regions B3 in the first direction (X-direction), and two regions B1 respectively disposed adjacent to each of the region B2 in the first direction (X-direction). A word line contact region may be disposed in each of the two regions B1, a sub-word line driver circuit may be disposed in each of the two regions B2, and other circuits may be disposed in the region B3. The order in which the word line contact region, the sub-word line driver circuit, and other circuits are disposed in each of the two regions B1, each of the two regions B2, and the region B3 is not limited.

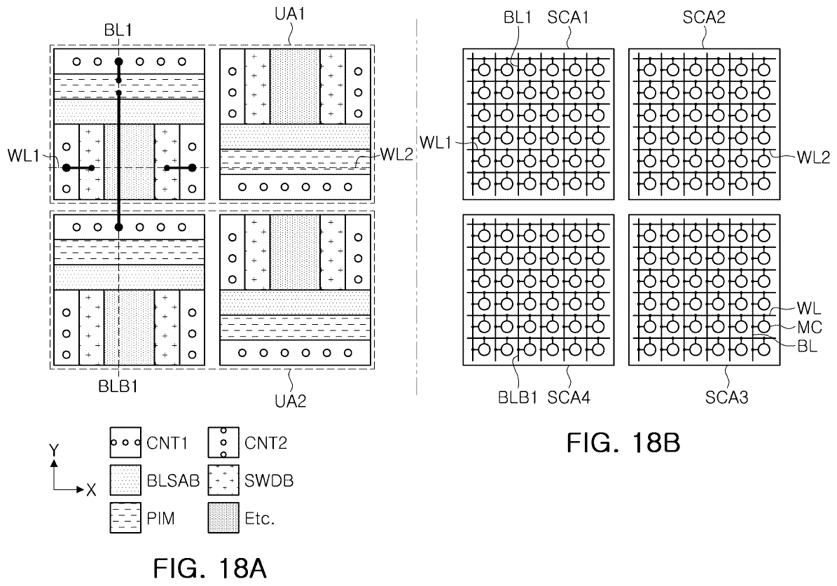

FIGS. 18A and 18B are views illustrating a core circuit region and a sub-cell region according to an example embodiment of the present disclosure.

FIG. 18A illustrates a first unit region UA1, and a second unit region UA2 adjacent to the first unit region UA1 in the second direction (Y-direction). Each of the first unit region UA1 and the second unit region UA2 corresponds to the unit region UA described with reference to FIG. 17.

FIG. 18B illustrates a first sub-cell region SCA1, a second sub-cell region SCA2, a third sub-cell region SCA3, and a fourth sub-cell region SCA4. In the third direction (Z-direction), the first sub-cell region SCA1 and the second sub-cell region SCA2 overlapping the first unit region UA1, and the third sub-cell region SCA3 and the fourth sub-cell region SCA4 overlapping the second unit region UA2. Each of a plurality of sub-cell regions SCA1 to SCA4 may include a plurality of word lines WL extending in the first direction (X-direction), a plurality of bit lines BL extending in the second direction (Y-direction), and a plurality of memory cells MC.

A connection structure of the unit region and the sub-cell regions according to an example embodiment of the present disclosure will be described by taking a first word line WL1 and a first bit line BL1 of the first sub-cell region SCA1, a second word line WL2 of the second sub-cell region SCA2, and a first complementary bit line BLB1 of the fourth sub-cell region SCA4 as an example.

In FIG. 18A, exemplary positions of the first word line WL1, the second word line WL2, the first bit line BL1, and the first complementary bit line BLB 1 are indicated by dashed lines, and a connection between the first word line WL1, the second word line WL2, the first bit line BL1, and the first complementary bit line BLB1 and the unit region UA is indicated by thick solid lines.

Similarly to that described with reference to FIG. 15A, in order to sense a bit line voltage in the first sub-cell region SCA1, a complementary bit line of the fourth sub-cell region SCA4 may be used. The first bit line BL1 may be connected to a bit line sense amplifier region BLSAB of the first sub-cell region SCA1 through a bit line contact region CNT1 of the first sub-cell region SCA1, and the first complementary bit line BLB1 may be connected to the bit line sense amplifier region BLSAB through a bit line contact region CNT1 of the fourth sub-cell region SCA4.

Similarly to that described with reference to FIG. 15A, a second word line WL2 of the second sub-cell region SCA2 may be connected to a sub-word line driver region SWDB of the second region U2. Additionally, the first word line WL1 of the first sub-cell region SCA1 may be connected to the sub-word line driver region SWDB of the second region U2 adjacent to the first region U1. In an example embodiment, word lines of the first sub-cell region SCA1 may extend to a word line contact region CNT2 of the second region U2.

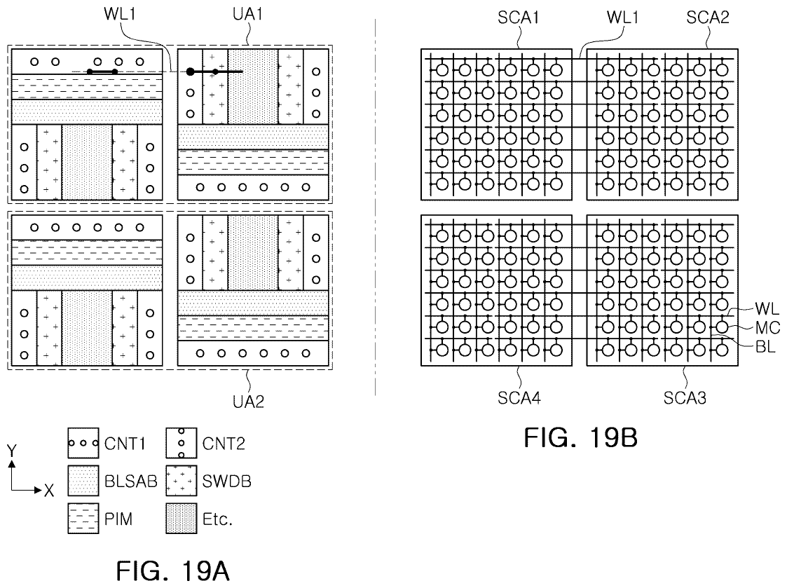

FIGS. 19A and 19B are views illustrating a core circuit region and a sub-cell region according to an example embodiment of the present disclosure.

The first and second unit regions UA1 and UA2 of FIG. 19A may have the same structure as that of the first and second unit regions UA1 and UA2 of FIG. 18A. Additionally, a plurality of sub-cell regions SCA1 to SCA4 of FIG. 19B may have a structure similar to that of a plurality of sub-cell regions SCA1 to SCA4 of FIG. 18B. However, unlike the plurality of sub-cell regions SCA1 to SCA4 of FIG. 18B, the first and second sub-cell regions SCA1 and SCA2 of FIG. 19B may have a shared word line, and the third and fourth sub-cell regions SCA3 and SCA4 of FIG. 19B may have a shared word line.

In FIG. 19B, a first word line WL1, one of the shared word lines of the first and second sub-cell regions SCA1 and SCA2, is illustrated. In FIG. 19A, a position corresponding to the first word line WL1 is indicated by dashed lines. A connection between the first word line WL1 and the unit region UA is illustrated by thick solid lines.

According to an example embodiment of the present disclosure, the first word line WL1 may be connected to the sub-word line driver region SWDB of the second region U2 through the word line contact region CNT2 included in the second region U2.

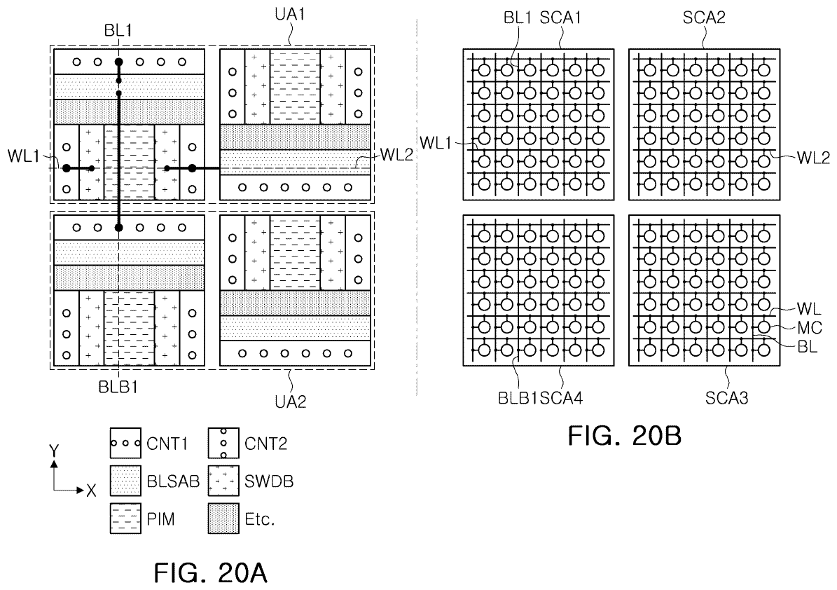

FIGS. 20A and 20B are views illustrating a core circuit region and a sub-cell region according to an example embodiment of the present disclosure.

First and second unit regions UA1 and UA2 of FIG. 20A may have a structure similar to that of the first and second unit regions UA1 and UA2 of FIG. 18A. Additionally, a plurality of sub-cell regions SCA1 to SCA4 of FIG. 20B may have the same structure as that of the plurality of sub-cell regions SCA1 to SCA4 of FIG. 18B. However, the first and second unit regions UA1 and UA2 of FIG. 20A may have a structure in which arrangements of a PIM circuit region PIM and other regions (Etc.) are exchanged with each other, as compared with the first and second unit regions UA1 and UA2 of FIG. 18A.

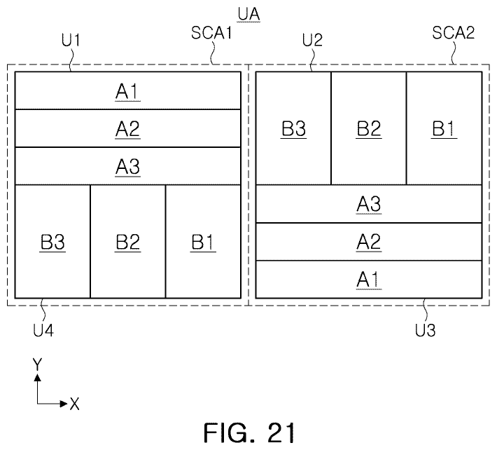

FIG. 21 is a view illustrating a core circuit region according to an example embodiment of the present disclosure.

A unit region UA of FIG. 21 may have a structure similar to that of the unit region UA described with reference to FIG. 17. However, unlike the unit region UA of FIG. 17, the unit region UA of FIG. 21 may include one region B1, one region B2, and one region B3 in which each of the second region U2 and the fourth region U4 is disposed adjacent to each other in the first direction (X-direction).

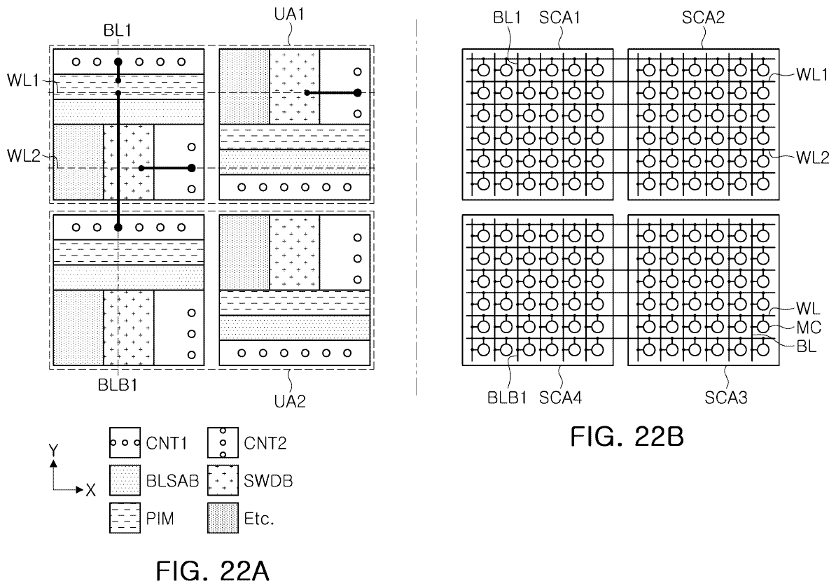

FIGS. 22A and 22B are views illustrating a core circuit region and a sub-cell region according to an example embodiment of the present disclosure.

FIG. 22A illustrates a first unit region UA1, and a second unit region UA2 adjacent to the first unit region UA1 in the second direction (Y-direction). Each of the first unit region UA1 and the second unit region UA2 corresponds to the unit region UA described above with reference to FIG. 21.

FIG. 22B illustrates a first sub-cell region SCA1, a second sub-cell region SCA2, a third sub-cell region SCA3, and a fourth sub-cell region SCA4. In the third direction (Z-direction), the first sub-cell region SCA1 and the second sub-cell region SCA2 overlapping the first unit region UA1, and the third sub-cell region SCA3 and the fourth sub-cell region SCA4 overlapping the second unit region UA2. Each of a plurality of sub-cell regions SCA1 to SCA4 may include a plurality of word lines WLs extending in the first direction (X-direction), a plurality of bit lines BLs extending in the second direction (Y-direction), and a plurality of memory cells MCs.

In an example embodiment, memory cells of the first and second sub-cell regions SCA1 and SCA2 adjacent to each other in the first direction (X-direction) may be connected to shared word lines extending across the first and second sub-cell regions SCA1 and SCA2. Similarly, the memory cells of the third and fourth sub-cell regions SCA3 and SCA4 may be connected to shared word lines extending across the third and fourth sub-cell regions SCA3 and SCA4. In FIG. 22B, a first word line WL1 and a second word line WL2, among the shared word lines, are illustrated.

In FIG. 22A, exemplary positions of the first word line WL1, the second word line WL2, the first bit line BL1, and the first complementary bit line BLB1 are indicated by dashed lines, and a connection between the first word line WL1, the second word line WL2, the first bit line BL1, and the first complementary bit line BLB1 and the unit region UA is indicated by thick solid lines.

Similarly to that described with reference to FIG. 18A, the first bit line BL1 may be connected to a bit line sense amplifier region BLSAB of the first sub-cell region SCA1 through a bit line contact region CNT1 of the first sub-cell region SCA1, and the first complementary bit line BLB1 may be connected to the bit line sense amplifier region BLSAB through the bit line contact region CNT1 of the fourth sub-cell region SCA4.

Among the shared word lines of the first and second sub-cell arrays SCA1 and SCA2, the first word line WL1 overlapping a word line contact region CNT2 of the second sub-cell array SCA2 may be connected to a sub-word line driver region SWDB of the second sub-cell array SCA2 through the word line contact region CNT2. Additionally, the second word line WL2 overlapping the word line contact region CNT2 of the first sub-cell array SCA1 may be connected to the sub-word line driver region SWDB of the first sub cell array SCA1 through the word line contact region CNT2.

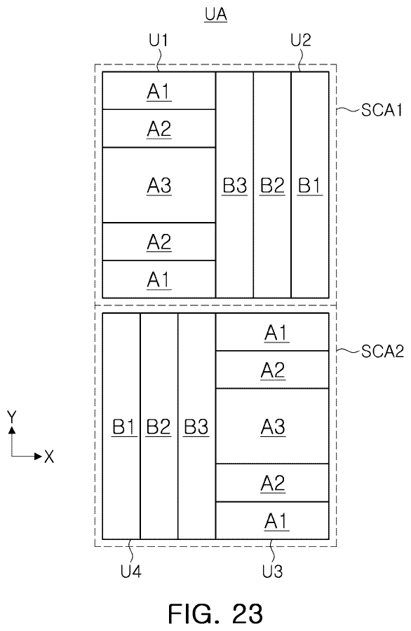

FIG. 23 is a view illustrating a core circuit region according to an example embodiment of the present disclosure.

Referring to FIG. 23, one unit region UA may include four regions divided in the first direction (X-direction) and the second direction (Y-direction). The four regions may be defined as first to fourth regions U1 to U4 in a clockwise order based on to the first region U1.

In an example of FIG. 23, one unit region UA may overlap, in the third direction (Z-direction), two sub-cell regions adjacent to each other in the second direction (Y-direction). The first region U1 and the second region U2 may overlap the first sub-cell region SCA1, and the third region U3 and the fourth region U4 may overlap the second sub-cell region SCA2.

Each of the first region U1 and the third region U3 may include a region A3, two regions A2 respectively disposed adjacent to the region A3 in the second direction (Y-direction), and two regions A1 respectively disposed adjacent to each of the two regions A2 in the second direction (Y-direction). A bit line contact region may be disposed in each of the two regions A1, a bit line sense amplifier circuit may be disposed in each of the two regions A2, and a PIM circuit may be disposed in the region A3. The order in which the bit line contact region, the bit line sense amplifier circuit, and the PIM circuit are disposed in each of the two regions A1, each of the two regions A2, and the region A3 is not limited.

Each of the second region U2 and the fourth region U4 may include region B1, region B2, and region B3, which are disposed adjacent to each other in the first direction (X-direction). A word line contact region, a sub-word line driver circuit, and other circuits may be disposed in region B1, region B2, and region B3. The order in which the word line contact region, the sub-word line driver circuit, and other circuits are disposed in region B1, region B2, and region B3 is not limited.

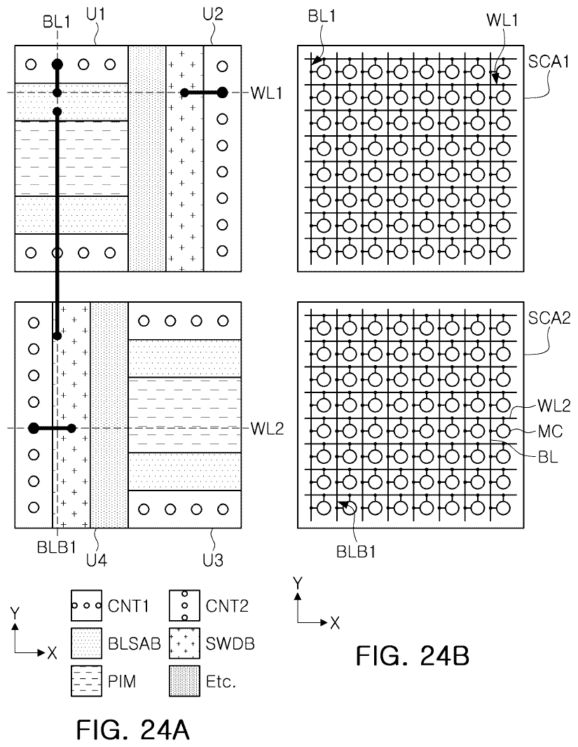

FIGS. 24A and 24B are views illustrating a core circuit region and a sub-cell region according to an example embodiment of the present disclosure.

FIG. 24B illustrates a first sub-cell region SCA1 and a second sub-cell region SCA2. The first sub-cell region SCA1 overlapping first and second regions U1 and U2, and the second sub-cell region SCA2 overlapping the third and fourth regions U3 and U4. Each of the first and second sub-cell regions SCA1 and SCA2 may include a plurality of word lines WL extending in the first direction (X-direction), a plurality of bit lines BL extending in the second direction (Y-direction), and a plurality of memory cells MC.

A connection structure of the unit region and the sub-cell regions according to an example embodiment of the present disclosure will be described by taking the first word line WL1 and the first bit line BLB1 of the first sub-cell region SCA1, and the second word line WL2 and the first complementary bit line BLB1 of the second sub-cell region SCA2 as an example.

In FIG. 24A, exemplary positions of the first word line WL1, the second word line WL2, the first bit line BL1, and the first complementary bit line BLB 1 are indicated by dashed lines, and a connection between the first word line WL1, the second word line WL2, the first bit line BL1, and the first complementary bit line BLB1 and the unit region UA is indicated by thick solid lines.

Similarly to that described with reference to FIG. 15A, in order to sense a bit line voltage in the first sub-cell region SCA1, a complementary bit line in the second sub-cell region SCA2 may be used. The first bit line BL1 may be connected to a bit line sense amplifier region BLSAB of the first sub-cell region SCA1 through a bit line contact region CNT1 of the first sub-cell region SCA1, and the first complementary bit line BLB1 may be connected to the bit line sense amplifier region BLSAB through the bit line contact region CNT1 of the first sub-cell region SCA1.

The first word line WL1 of the first sub-cell region SCA1 may be connected to a sub-word line driver region SWDB of the second region U2 through a word line contact region CNT2 of the second region U2. Additionally, the second word line WL2 of the second sub-cell region SCA2 may be connected to a sub-word line driver region SWDB of the fourth region U4 through a word line contact region CNT2 of the fourth region U4.

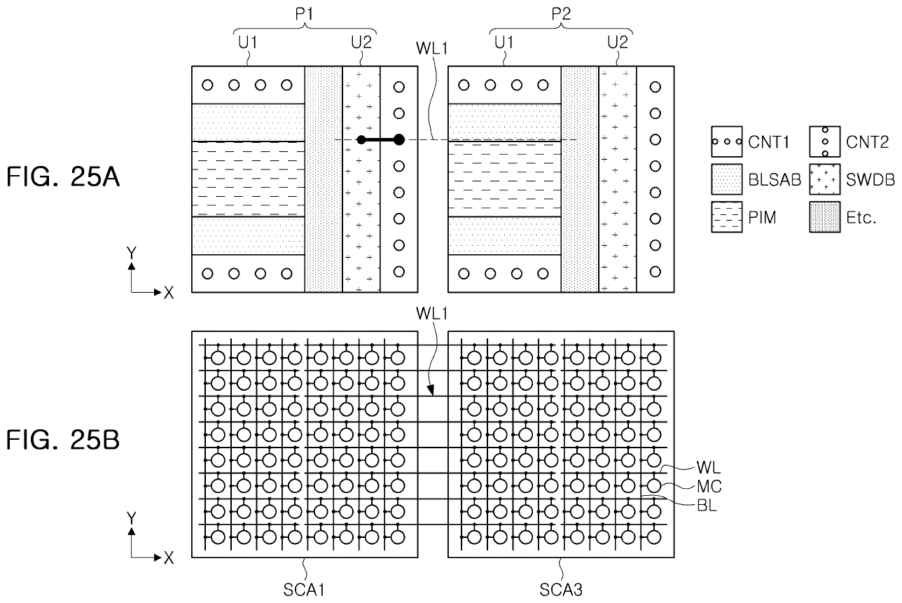

FIGS. 25A and 25B are views illustrating a core circuit region and a sub-cell region according to an example embodiment of the present disclosure.

FIG. 25A illustrates a first portion P1 and a second portion P2. Each of the first portion P1 and the second portion P2 including the first region U1 and the second region U2 described above with reference to FIG. 23. Specifically, FIG. 25A illustrates the first portion P1 overlapping the first sub-cell region SCA1, and the second portion P2 overlapping a third sub-cell region SCA3 adjacent to the first sub-cell region SCA1 in the first direction (X-direction).

The first sub-cell region SCA1 and the third sub-cell region SCA3 of FIG. 25B may have shared word lines, similarly to the first sub-cell region SCA1 and the second sub-cell region SCA2 illustrated in FIG. 16B.

In FIG. 25B, a first word line WL1, one of the shared word lines of the first and third sub-cell regions SCA1 and SCA3, is illustrated. In FIG. 25A, a position corresponding to the first word line WL1 is indicated by dashed lines. A connection between the first word line WL1 and the unit region UA is illustrated by thick solid lines.

According to an example embodiment of the present disclosure, the first word line WL1 may be connected to a sub-word line driver region SWDB of the second region U2 through a word line contact region CNT2 included in the second region U2 of the first sub-cell region SCA1.

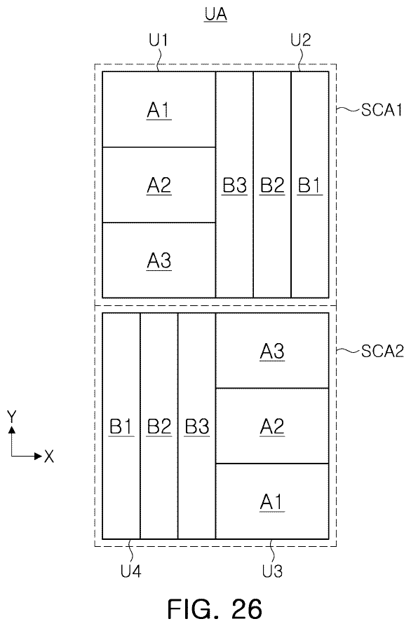

FIG. 26 is a view illustrating a core circuit region according to an example embodiment of the present disclosure.

A unit region UA of FIG. 26 may have a structure similar to that of the unit region UA described with reference to FIG. 23. However, unlike the unit region UA of FIG. 23, the unit region UA of FIG. 26 may include one region A1, one region A2 and one region A3 adjacent to each of a first region U1 and a third region U3 in the second direction (Y-direction).

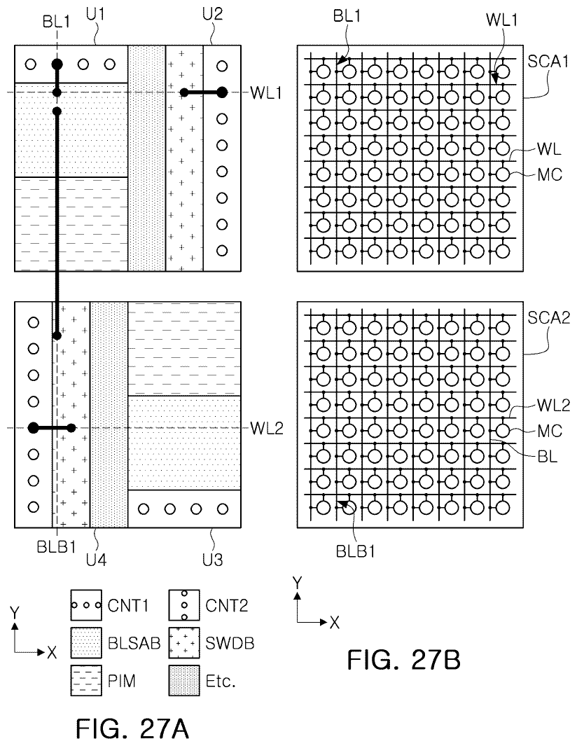

FIGS. 27A and 27B are views illustrating a core circuit region and a sub-cell region according to an example embodiment of the present disclosure.

FIG. 27A illustrates a first unit region UA1 and a second unit region UA2 adjacent to the first unit region UA1 in the second direction (Y-direction). Each of the first unit region UA1 and the second unit region UA2 corresponds to the unit region UA described above with reference to FIG. 26.

FIG. 27B illustrates a first sub-cell region SCA1 overlapping the first and second regions U1 and U2, and a second sub-cell region SCA2 overlapping the third and fourth regions U3 and U4. Each of the first and second sub-cell regions SCA1 and SCA2 may include a plurality of word lines WLs extending in the first direction (X-direction), a plurality of bit lines BLs extending in the second direction (Y-direction), and a plurality of memory cells MCs.

A connection structure of the unit region and the sub-cell regions according to an example embodiment of the present disclosure will be described by taking a first word line WL1 and a first bit line BLB1 of the first sub-cell region SCA1, and a second word line WL2 and a first complementary bit line BLB1 of the second sub-cell region SCA2 as an example.

In FIG. 27A, exemplary positions of the first word line WL1, the second word line WL2, the first bit line BL1, and the first complementary bit line BLB1 are indicated by dashed lines, and a connection between the first word line WL1, the second word line WL2, the first bit line BL1, and the first complementary bit line BLB1 and the unit region UA is indicated by thick solid lines.

In order to detect a bit line voltage in the first sub-cell region SCA1, a complementary bit line of the second sub-cell region SCA2 may be used. The first bit line BL1 may be connected to a bit line sense amplifier region BLSAB of the first sub-cell region SCA1 through a bit line contact region CNT1 of the first sub-cell region SCA1. Similarly, the first complementary bit line BLB1 may be connected to a bit line sense amplifier region BLSAB the bit line contact region CNT1 of the first sub-cell region SCA1.

The first word line WL1 of the first sub-cell region SCA1 may be connected to a sub-word line driver region SWDB of the second region U2 through a word line contact region CNT2 of the second region U2. Additionally, the second word line WL2 of the second sub-cell region SCA2 may be connected to a sub-word line driver region SWDB of the fourth region U4 through a word line contact region CNT2 of the fourth region U4.

The unit region described with reference to FIGS. 14 to 27B includes region A1, region A2, region A3, region B1, region B2 and region B3, but the present disclosure is not limited thereto. For example, similarly to that described with reference to FIGS. 10 to 13, a structure connecting the bit lines and the bit line sense amplifier may overlap the bit line sense amplifier region BLSAB, and a structure connecting the word lines and the sub-word line driver circuit may overlap the sub-word line driver region SWDB.

According to an example embodiment of the present disclosure, the unit control circuit for controlling one or more sub-cell blocks may be efficiently connected to the sub-cell block by being disposed in regions having a windmill wing shape in the unit region. For example, the bit line sense amplifier circuits of the unit region may be efficiently connected to all bit lines arranged in the first direction (X-direction), and the sub-word line driver circuits in the unit region may be efficiently connected to all word lines arranged in the second direction (Y-direction).

Furthermore, a PIM circuit may be disposed in a remaining region without disposing bit line sense amplifier circuits, sub-word line driver circuits, and other circuits in the unit region. Accordingly, data stored in the sub-cell block may be efficiently processed, and an area of the core circuit region including the PIM circuit may not increase beyond an area of the memory cell array region.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

1. A memory device, comprising:
a memory cell array circuit including a plurality of sub-cell regions disposed in a first direction and a second direction, the plurality of sub-cell regions respectively including a plurality of memory cells respectively connected to a plurality of word lines extending in the first direction and a plurality of bit lines extending in the second direction, the second direction intersecting the first direction; and
a core circuit including a plurality of unit regions respectively overlapping at least one sub-cell region, among the plurality of sub-cell regions, in a third direction, perpendicular to the first direction and the second direction,
wherein each of the plurality of unit regions includes a first region, a second region adjacent to the first region in the first direction, a third region adjacent to the second region in the second direction, and a fourth region adjacent to the third region in the first direction, and the fourth region is adjacent to the first region in the second direction,
wherein the first region and the third region include a bit line sense amplifier circuit respectively connected to the plurality of bit lines, and a processing in memory (PIM) circuit adjacent to the bit line sense amplifier circuit in the second direction and connected to the bit line sense amplifier circuit, and
wherein the second region and the fourth region include a sub-word line driver circuit respectively connected to the plurality of word lines, and a row driver circuit included in a region adjacent to the sub-word line driver circuit in the first direction.

2. The memory device of claim 1, wherein the first region and the third region include a plurality of first through silicon vias (TSVs) connecting the plurality of bit lines and the bit line sense amplifier circuit, and further includes a bit line contact region adjacent to the bit line sense amplifier circuit or the PIM circuit in the second direction, and
wherein the second region and the fourth region include a plurality of second TSVs connecting the plurality of word lines and the sub-word line driver circuit, and further includes a word line contact region adjacent to the sub-word line driver circuit or the row driver circuit in the first direction.

3. The memory device of claim 1, wherein the plurality of sub-cell regions include a first sub-cell region and a second sub-cell region adjacent to each other in the second direction,
wherein the plurality of unit regions include a first unit region overlapping the first sub-cell region and a second unit region overlapping the second sub-cell region in the third direction, and
wherein the bit line sense amplifier circuit of the first unit region is connected to a plurality of bit lines included in the first unit region and a plurality of bit lines included in the second sub-cell region.

4. The memory device of claim 1, wherein the plurality of sub-cell regions include a first sub-cell region and a second sub-cell region adjacent to each other in the first direction,
wherein the plurality of unit regions include a first unit region overlapping the first sub-cell region and a second unit region overlapping the second sub-cell region in the third direction,
wherein some of the memory cells included in the first sub-cell region and some of the memory cells included in the second sub-cell region are connected to a plurality of shared word lines extending across the first sub-cell region and the second sub-cell region, and
wherein first shared word lines, among the plurality of shared word lines, are connected to a sub-word line driver circuit included in a second region of the first unit region, and second shared word lines, among the plurality of shared word lines, are connected to a sub-word line driver circuit included in a fourth region of the second unit region.

5. The memory device of claim 1, wherein each of the plurality of sub-cell regions includes:
a plurality of first TSVs connecting the plurality of bit lines and the bit line sense amplifier circuit and overlapping the bit line sense amplifier circuit in the third direction, and
a plurality of second TSVs connecting the plurality of word lines and the sub-word line driver circuit and overlapping the sub-word line driver circuit in the third direction.

6. The memory device of claim 1, wherein the plurality of sub-cell regions include:
a first sub-cell region overlapping the first region in the third direction;
a second sub-cell region overlapping the second region in the third direction;
a third sub-cell region overlapping the third region in the third direction; and
a fourth sub-cell region overlapping the fourth region in the third direction,
wherein the bit line sense amplifier circuit includes a first bit line sense amplifier circuit and a second bit line sense amplifier circuit adjacent to the PIM circuit in the second direction, and
wherein the sub-word line driver circuit includes a first sub-word line driver circuit and a second sub-word line driver circuit adjacent to the row driver circuit in the first direction.

7. The memory device of claim 6, wherein the bit line sense amplifier circuit in the first region is connected to a plurality of bit lines included in the first sub-cell region and a plurality of bit lines included in the fourth sub-cell region, and
wherein the bit line sense amplifier circuit in the third region is connected to a plurality of bit lines included in the third sub-cell region and a plurality of bit lines included in the second sub-cell region.

8. The memory device of claim 7, wherein the first sub-word line driver circuit of the second region is connected to a plurality of word lines included in the first sub-cell region, and the second sub-word line driver circuit of the second region is connected to a plurality of word lines included in the second sub-cell region, and
the first sub-word line driver circuit in the fourth region is connected to a plurality of word lines included in the third sub-cell region, and the second sub-word line driver circuit in the fourth region is connected to a plurality of word lines included in the fourth sub-cell region.

9. The memory device of claim 7, wherein some of the memory cells included in the first sub-cell region and some of the memory cells included in the second sub-cell region are connected to a plurality of shared word lines extending across the first sub-cell region and the second sub-cell region, and
wherein the plurality of shared word lines are connected to the first sub-word line driver of the second region.

10. The memory device of claim 1, further comprising:
a first sub-cell region overlapping the first region and the fourth region in the third direction, and a second sub-cell region overlapping the second region and the third region in the third direction,
wherein the sub-word line driver circuit includes a first sub-word line driver and a second sub-word line driver adjacent to the row driver circuit in the second direction.

11. The memory device of claim 1, further comprising:
a first sub-cell region overlapping the first region and the fourth region in the third direction, and a second sub-cell region overlapping the second region and the third region in the third direction,
wherein memory cells included in the first sub-cell region and memory cells included in the second sub-cell region are connected to a plurality of shared word lines extending across the first sub-cell region and the second sub-cell region,
first shared word lines overlapping the second region, among the plurality of shared word lines, are connected to the sub-word line driver circuit included in the second region, and
second shared word lines overlapping the fourth region, among the plurality of shared word lines, are connected to the sub-word line driver circuit included in the fourth region.

12. The memory device of claim 11, further comprising:
a third sub-cell region adjacent to the first sub-cell region in the second direction,
wherein the bit line sense amplifier circuit included in the first region are connected to the plurality of bit lines included in the first sub-cell region and the plurality of bit lines included in the third sub-cell region adjacent.

13. The memory device of claim 1, further comprising:
a first sub-cell region overlapping the first region and the second region in the third direction, and a second sub-cell region overlapping the third region and the fourth region in the third direction,
wherein the bit line sense amplifier circuit included in the first region is connected to the plurality of bit lines included in the first sub-cell region and overlapping the first region, and the plurality of bit lines included in the second sub-cell region and overlapping the fourth region, and
wherein the bit line sense amplifier circuit included in the third region is connected to the plurality of bit lines included in the second sub-cell region and overlapping the third region, and the plurality of bit lines included in the first sub-cell region and overlapping the second region.

14. The memory device of claim 13, wherein the bit line sense amplifier circuit includes a first bit line sense amplifier circuit and a second bit line sense amplifier circuit respectively disposed adjacent to the PIM circuit in the second direction.

15-21. (canceled)

22. A memory device, comprising:
a first semiconductor layer including a first substrate, and including a plurality of sub-cell blocks including a plurality of word lines extending in a first direction, parallel to an upper surface of the first substrate, a plurality of bit lines extending in a second direction, parallel to the upper surface of the first substrate and intersecting the first direction, a plurality of memory cells connected to the plurality of bit lines and the plurality of word lines, a plurality of first through silicon vias (TSVs) contacting the plurality of bit lines and spaced apart from the plurality of memory cells in the second direction, and a plurality of second TSVs contacting the plurality of word lines and spaced apart from the plurality of memory cells in the first direction; and
a second semiconductor layer including a second substrate including a plurality of unit regions overlapping the plurality of sub-cell blocks on a first surface,
wherein each of the plurality of unit regions includes first to fourth regions adjacent to each other in the first direction and the second direction and defined in a clockwise order on the upper surface of the first substrate,
wherein the first region and the third region include a bit line sense amplifier circuit electrically connected to the plurality of bit lines through the plurality of first TSVs, respectively, and a processing in memory (PIM) circuit connected to the bit line sense amplifier circuit through conductive patterns, and
wherein the second region and the fourth region include a sub-word line driver circuit respectively connected to the plurality of word lines through the plurality of second TSVs, and a row decoder circuit connected to the sub-word line driver circuit through conductive patterns.

23. The memory device of claim 22, wherein the first semiconductor layer further includes:
an insulating layer covering the plurality of sub-cell blocks; and
a bonding layer formed in an upper portion of the insulating layer and contacting a second surface opposite to the first surface of the second substrate, and
wherein the second semiconductor layer further includes:
third TSVs adjacent to the plurality of unit regions in the first direction and connecting the plurality of first TSVs and the bit lines; and
fourth TSVs adjacent to the plurality of unit regions in the second direction and connecting the plurality of second TSVs and the word lines.

24. The memory device of claim 22, wherein the plurality of word lines are buried in the second substrate, and the plurality of bit lines and the plurality of memory cells are on the first surface of the second substrate.

25. The memory device of claim 22, wherein the first semiconductor layer further includes a plurality of first bonding pads respectively contacting the plurality of first TSVs and the plurality of second TSVs,
wherein the second semiconductor layer further includes a plurality of second bonding pads in contact with the conductive patterns, and
wherein the first bonding pads and the second bonding pads are in contact with each other.

26. A memory device, comprising:
a first semiconductor layer including a first substrate including a plurality of unit regions on an upper surface thereof, wherein the plurality of unit regions include first to fourth regions adjacent to each other in a first direction and a second direction, parallel to an upper surface of the first substrate and defined in a clockwise order, each of the first region and the third region includes a bit line sense amplifier circuit and a processing in memory (PIM) circuit connected to the bit line sense amplifier circuit, and the second region and the fourth region include a sub-word line driver circuit and a row decoder circuit connected to the sub-word line driver circuit; and
a second semiconductor layer disposed on the first semiconductor layer and including a plurality of memory cell structures respectively including a plurality of word lines extending in a first direction, parallel to an upper surface of the first substrate, a plurality of bit lines extending in a second direction, parallel to the upper surface of the first substrate and intersecting the first direction, and a plurality of memory cells connected to the plurality of bit lines and the plurality of word lines,
wherein the second semiconductor layer includes:
a plurality of first through silicon vias (TSVs) overlapping the first region and the third region in a third direction, perpendicular to the first substrate, and electrically connecting the plurality of bit lines and the bit line sense amplifier circuit in a position adjacent to one of the plurality of memory cell structures in the second direction; and
a plurality of second TSVs overlapping the second region and the fourth region in the third direction, and electrically connecting the plurality of word lines and the sub-word line driver circuit in the position adjacent to one of the plurality of memory cell structures in the first direction.

27. The memory device of claim 26, wherein the first semiconductor layer further includes:
an insulating layer covering the bit line sense amplifier circuit, the PIM circuit, the sub-word line driver circuit and the row decoder circuit, and a bonding layer contacting an upper surface of the insulating layer,
wherein the plurality of first TSVs penetrate through the bonding layer and the insulating layer and are in contact with a conductive pattern connected to the bit line sense amplifier circuit, and
wherein the plurality of second TSVs penetrate through the bonding layer and the insulating layer and are in contact with a conductive pattern connected to the sub-word line driver circuit.

28. (canceled)

29. (canceled)
